(19) United States
(12) Patent Application Publication
(10) Pub. No.: US 2021/0143218 A1
(43) Pub. Date: May 13, 2021

(54) IMAGING DEVICE

(71) Applicant: Panasonic Intellectual Property Management Co., Ltd., Osaka (JP)

(72) Inventors: YOSHIAKI SATOU, Kyoto (JP); YOSHIHIRO SATO, Osaka (JP); MASASHI MURAKAMI, Kyoto (JP)

(21) Appl. No.: 17/154,011

(22) Filed: Jan. 21, 2021

Related U.S. Application Data
(63) Continuation of application No. PCT/JP2019/025285, filed on Jun. 26, 2019.

(30) Foreign Application Priority Data
Oct. 30, 2018 (JP) 2018-203932

(51) Int. Cl. H01L 27/30; H01L 27/146; H01L 23/522

(52) U.S. Cl. CPC H01L 27/307; H01L 27/14665; H01L 27/14603; H01L 23/5223; H01L 23/5225; H01L 27/14636

(57) ABSTRACT

An imaging device includes a semiconductor substrate, a first pixel that performs photoelectric conversion, and a first shield. The first pixel includes a first diffusion region that is present in the semiconductor substrate, a first wiring line connected to the first diffusion region, a first transistor, and a first voltage line that makes up at least part of a voltage supply path to a drain or a source of the first transistor. A first signal charge obtained by photoelectric conversion performed by the first pixel flows through the first wiring line. The first signal charge flows into a gate of the first transistor via the first wiring line. Voltages that are different from each other are applied to the first voltage line. A distance between the first voltage line and the first shield is smaller than a distance between the first voltage line and the first wiring line.

### BACKGROUND

### 1. Technical Field

The present disclosure relates to imaging devices.

### 2. Description of the Related Art

Image sensors are used in digital cameras and the like. Examples of such image sensors include charge coupled device (CCD) image sensors and complementary metal oxide semiconductor (CMOS) image sensors. In these image sensors, photodiodes are provided on a semiconductor substrate.

Meanwhile, Japanese patent Nos. 6108280 and 6124217 proposed imaging devices each having a multilayer structure formed of a semiconductor substrate and a photoelectric conversion unit. In these multilayer type imaging devices of Japanese patent Nos. 6108280 and 6124217, the photoelectric conversion unit includes a photoelectric conversion layer that performs photoelectric conversion. Electric charge is generated by photoelectric conversion. This electric charge is accumulated in a charge accumulation region (referred to as “floating diffusion”). On the semiconductor substrate, a CCD circuit or a CMOS circuit is provided. A signal corresponding to the amount of the electric charge accumulated in the charge accumulation region is read out through the CCD circuit or the CMOS circuit.

### SUMMARY

There is a demand for techniques for suppressing noise.

In one general aspect, the techniques disclosed here feature an imaging device including: a semiconductor substrate; a first pixel that performs photoelectric conversion; and a first shield, wherein the first pixel includes a first diffusion region that is present in the semiconductor substrate, a first wiring line connected to the first diffusion region, the first wiring line being a wiring line through which a first signal charge obtained by photoelectric conversion performed by the first pixel flows, a first transistor including a gate into which the first signal charge flows via the first wiring line, and a first voltage line that makes up at least part of a voltage supply path to a drain or a source of the first transistor, the first voltage line being a voltage line to which voltages that are different from each other are to be applied, and a distance between the first voltage line and the first shield is smaller than a distance between the first voltage line and the first wiring line.

The present disclosure provides a technique for suppressing noise.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating an exemplary circuit configuration of an imaging device;

FIG. 2 is a schematic diagram illustrating an exemplary circuit configuration of a pixel;

FIG. 3 is a schematic diagram illustrating an exemplary circuit configuration of a pixel;

FIG. 4 is a schematic diagram illustrating an exemplary circuit configuration of an imaging device;

FIG. 5 is a timing chart for illustrating an exemplary operation of a readout circuit;

FIG. 6 is a plan view schematically illustrating an exemplary layout of wiring lines in a pixel;

FIG. 7A is a plan view schematically illustrating an exemplary layout of wiring lines in a pixel;

FIG. 7B is a plan view schematically illustrating an exemplary layout of wiring lines in a pixel;

FIG. 8 is a plan view schematically illustrating an exemplary layout of wiring lines in a pixel;

FIG. 9 is a sectional view schematically illustrating an exemplary section in a pixel;

FIG. 10 is a sectional view schematically illustrating an exemplary section in a pixel;

FIG. 11 is a sectional view schematically illustrating an exemplary section in a pixel;

FIG. 12 is a sectional view schematically illustrating an exemplary section in a pixel;

FIG. 13A is a sectional view schematically illustrating an exemplary section in a pixel;

FIG. 13B is a sectional view schematically illustrating an exemplary section in a pixel;

FIG. 13C is a sectional view schematically illustrating an exemplary section in a pixel;

FIG. 14 is a sectional view schematically illustrating an exemplary section in a pixel;

FIG. 15 is a schematic diagram illustrating an exemplary circuit configuration of an imaging device;

FIG. 16 is a schematic diagram illustrating an exemplary circuit configuration of a pixel;

FIG. 17 is a timing chart for illustrating an exemplary operation of a readout circuit;

FIG. 18 is a plan view schematically illustrating an exemplary layout of wiring lines in a pixel;

FIG. 19 is a plan view schematically illustrating an exemplary layout of wiring lines in a pixel;

FIG. 20 is a sectional view schematically illustrating an exemplary section in a pixel;

FIG. 21 is a sectional view schematically illustrating an exemplary section in a pixel;

FIG. 22 is a plan view schematically illustrating an exemplary layout of wiring lines in a pixel;

FIG. 23 is a sectional view schematically illustrating an exemplary section in a pixel;

FIG. 24A is a plan view schematically illustrating an exemplary layout of wiring lines in a pixel;

FIG. 24B is a plan view schematically illustrating an exemplary layout of wiring lines in a pixel;

FIG. 25 is a sectional view schematically illustrating an exemplary section in a pixel;

FIG. 26 is a sectional view schematically illustrating an exemplary section in a pixel; and

FIG. 27 is a block diagram of a camera system.

### DETAILED DESCRIPTION

Overview of Aspects According to the Present Disclosure

An imaging device according to a first aspect of the present disclosure includes

a semiconductor substrate, a first pixel that performs photoelectric conversion, and a first shield, wherein

the first pixel includes
a first diffusion region that is present in the semiconductor substrate,
a first wiring line connected to the first diffusion region, the first wiring line being a wiring line through which a first signal charge obtained by photoelectric conversion performed by the first pixel flows,
a first transistor including a gate into which the first signal charge flows via the first wiring line, and
a first voltage line that makes up at least part of a voltage supply path to a drain or a source of the first transistor, the first voltage line being a voltage line to which voltages that are different from each other are to be applied, and

a distance between the first voltage line and the first shield is smaller than a distance between the first voltage line and the first wiring line.

The first aspect is suitable for noise suppression. Specifically, the first shield of the first aspect is suitable for suppressing noise from entering the first wiring line due to the first voltage line.

An imaging device according to a second aspect of the present disclosure includes

a semiconductor substrate, a first pixel that performs photoelectric conversion, a second pixel that performs photoelectric conversion, and a first shield, wherein

the first pixel and the second pixel are adjacent to each other,

the first pixel includes
a first diffusion region that is present in the semiconductor substrate, and
a first wiring line connected to the first diffusion region, the first wiring line being a wiring line through which a first signal charge obtained by photoelectric conversion performed by the first pixel flows,

the second pixel includes
a first transistor including a gate into which a second signal charge obtained by photoelectric conversion performed by the second pixel flows, and
a first voltage line that makes up at least part of a voltage supply path to a drain or a source of the first transistor, the first voltage line being a voltage line to which voltages that are different from each other are to be applied, and

a distance between the first voltage line and the first shield is smaller than a distance between the first voltage line and the first wiring line.

The second aspect is suitable for noise suppression. Specifically, the first shield of the second aspect is suitable for suppressing noise from entering the first wiring line due to the first voltage line.

In a third aspect of the present disclosure, for example, in the imaging device according to the first aspect or the second aspect,

a voltage of the first voltage line may be changed in a state where a voltage of the first shield is fixed.

The first shield of the third aspect is suitable for suppressing noise from entering the first wiring line due to the first voltage line.

In a fourth aspect of the present disclosure, for example, the imaging device according to one of the first to third aspects may further include a first wiring layer provided at a first position in a thickness direction of the semiconductor substrate, wherein

the first voltage line may be placed in the first wiring layer,

the first shield may be placed in the first wiring layer,

the first wiring line may include a first part located in the first wiring layer, and

in plan view, the first shield may be located between the first part and the first voltage line.

In some cases, the first voltage line and the first shield are placed in the same wiring layer. In such a case, the first shield of the fourth aspect may produce the foregoing noise suppression effect.

In a fifth aspect of the present disclosure, for example, the imaging device according to one of the first to third aspects may further include a first wiring layer and a second wiring layer that are provided at positions different from each other in a thickness direction of the semiconductor substrate, wherein

the first voltage line may be placed in the first wiring layer,

the first shield may be placed in the second wiring layer,

the first wiring line may include a first part located in the second wiring layer, and

in plan view, the first shield may be located between the first part and the first voltage line.

In some cases, the first voltage line and the first shield are arranged in wiring layers different from each other. In such a case, the first shield of the fifth aspect may produce the foregoing noise suppression effect.

In a sixth aspect of the present disclosure, for example, the imaging device according to one of the first to fifth aspects may further include a second shield, wherein a distance between the first voltage line and the second shield may be smaller than the distance between the first voltage line and the first wiring line.

The second shield of the sixth aspect is suitable for suppressing noise from entering the first wiring line due to the first voltage line.

In a seventh aspect of the present disclosure, for example, in the imaging device according to one of the first to sixth aspects,

the distance between the first shield and the first voltage line may be smaller than a distance between the first shield and the first wiring line.

The first shield of the seventh aspect is suitable for suppressing noise from entering the first wiring line due to the first voltage line.

In an eighth aspect of the present disclosure, for example, in the imaging device according to one of the first to seventh aspects,

in plan view, no wiring line may be present between the first voltage line and the first shield.

The first shield of the eighth aspect is suitable for suppressing noise from entering the first wiring line due to the first voltage line.

In a ninth aspect of the present disclosure, for example, in the imaging device according to one of the first to eighth aspects,

the first shield may include a first shield line,

a distance between the first voltage line and the first shield line may be smaller than the distance between the first voltage line and the first wiring line.

The first shield line of the ninth aspect is suitable for suppressing noise from entering the first wiring line due to the first voltage line.

In a tenth aspect of the present disclosure, for example, the imaging device according to one of the first to ninth aspects may further include a capacitive element, wherein

the capacitive element may include
a pair of electrodes, and
a dielectric layer interposed between the pair of electrodes, and the first shield may include a first electrode of the pair of electrodes.

The electrode of the capacitive element according of the tenth aspect may function as a shield for the foregoing noise suppression.

In an eleventh aspect of the present disclosure, for example, in the imaging device according to the tenth aspect,

the first electrode of the pair of electrodes may be closer to the first voltage line than a second electrode of the pair of electrodes may be, and

a distance between the first electrode of the pair of electrodes and the first voltage line may be smaller than the distance between the first wiring line and the first voltage line.

The first electrode of the pair of electrodes of the eleventh aspect is suitable for suppressing noise from entering the first wiring line due to the first voltage line.

In a twelfth aspect of the present disclosure, for example, the imaging device according to one of the first to eleventh aspects may further include a first photoelectric converter, wherein

the first photoelectric converter may include a first electrode, a second electrode, and a photoelectric conversion layer placed between the first electrode and the second electrode,

the photoelectric conversion layer may convert incident light into the first signal charge, and

the first wiring line may connect the second electrode and the first diffusion region.

The first wiring line of the twelfth aspect is suitable for allowing the first signal charge to flow from the first photoelectric converter to the first diffusion region. The first electrode and the second electrode of the twelfth aspect are suitable for adjusting the amount of the first signal charge generated in the photoelectric conversion layer by adjusting an electric field applied to the photoelectric conversion layer.

In a thirteenth aspect of the present disclosure, for example, in the imaging device according to the twelfth aspect,

in the thickness direction of the semiconductor substrate, the first voltage line and the first shield may be located between the first photoelectric converter and the semiconductor substrate.

The arrangement of the first voltage line and the first shield of the thirteenth aspect is one example of the arrangement that may be adopted in the twelfth aspect.

In a fourteenth aspect of the present disclosure, for example, the imaging device according to the twelfth aspect or the thirteenth aspect may further include a plurality of wiring layers provided at positions different from each other in the thickness direction of the semiconductor substrate, wherein

the plurality of wiring layers may include a first wiring layer,

the first voltage line may be placed in the first wiring layer, and

of the plurality of wiring layers, the first wiring layer may be a proximal layer in a case where a layer closest to the first photoelectric converter is defined as the proximal layer.

The fourteenth aspect is suitable for avoiding the arrangement of the signal line and the power source line on the side of the first photoelectric converter of the first voltage line. This relaxes part of the design that has been made in consideration of the voltage changes in the first voltage line and thus facilitates wiring.

In a fifteenth aspect of the present disclosure, for example, in the imaging device according to one of the twelfth to fourteenth aspects,

in the thickness direction of the semiconductor substrate, the second electrode, the first shield, the first voltage line, and the semiconductor substrate may be arranged in order of mention.

The first shield of the fifteenth aspect is suitable for suppressing noise from entering the second electrode due to the first voltage line.

In a sixteenth aspect of the present disclosure, for example, in the imaging device according to the fifteenth aspect,

the first shield may include a first shield line, and

in plan view, the first shield line may overlap with at least part of the first voltage line.

The first shield line of the sixteenth aspect is suitable for suppressing noise from entering the second electrode due to the first voltage line.

In a seventeenth aspect of the present disclosure, for example, in the imaging device according to the sixteenth aspect,

in plan view, the first shield line may overlap with whole of the first voltage line.

The first shield line of the seventeenth aspect is suitable for suppressing noise from entering the second electrode due to the first voltage line.

In an eighteenth aspect of the present disclosure, for example, the imaging device according to one of the twelfth to seventeenth aspects may further include a third electrode, wherein

the third electrode and the second electrode may be provided on one side of the photoelectric conversion layer,

the third electrode may be electrically isolated from the second electrode, and

the third electrode may be electrically connected to the first shield.

The configuration of the eighteenth aspect is one example of the configuration in which the third electrode and the first shield can share a common voltage supply source.

In a nineteenth aspect of the present disclosure, for example, in the imaging device according to one of the twelfth to eighteenth aspects,
the distance between the first shield and the first voltage line may be smaller than a distance between the second electrode and the first voltage line in the thickness direction of the semiconductor substrate, and
   smaller than the distance between the first voltage line and the first wiring line in plan view.

The first shield of the nineteenth aspect is suitable for suppressing noise from entering the second electrode due to the first voltage line and for suppressing noise from entering the first wiring line due to the first voltage line.

In a twentieth aspect of the present disclosure, for example, in the imaging device according to one of the first to eleventh aspects,
the first diffusion region and the semiconductor substrate may make up a first photodiode,
the first photodiode may convert incident light into the first signal charge, and
the first wiring line may electrically connect the first transistor and the first diffusion region.

The twentieth aspect can achieve the imaging device that uses the photodiode.

An imaging device according to a twenty-first aspect of the present disclosure includes
a semiconductor substrate, a first pixel that performs photoelectric conversion, and a first shield, wherein
the first pixel includes
   a first diffusion region that is present in the semiconductor substrate,
   a first wiring line connected to the first diffusion region, the first wiring line being a wiring line through which a signal charge obtained by photoelectric conversion performed by the first pixel flows,
   a first transistor, and
   a first voltage line that makes up at least part of a voltage supply path to a gate of the first transistor, the first voltage line being a voltage line to which voltages that are different from each other are to be applied, and
a distance between the first voltage line and the first shield is smaller than a distance between the first voltage line and the first wiring line.

The twenty-first aspect is suitable for noise suppression. Specifically, the first shield of the twenty-first aspect is suitable for suppressing noise from entering the first wiring line due to the first voltage line.

An imaging device according to a twenty-second aspect of the present disclosure includes
a semiconductor substrate, a first pixel that performs photoelectric conversion, a second pixel that performs photoelectric conversion, and a first shield, wherein
the first pixel and the second pixel are adjacent to each other,
the first pixel includes
   a first transistor, and
   a first voltage line that makes up at least part of a voltage supply path to a gate of the first transistor, the first voltage line being a voltage line to which voltages that are different from each other are to be applied,
the second pixel includes
   a first diffusion region that is present in the semiconductor substrate, and
   a first wiring line connected to the first diffusion region, the first wiring line being a wiring line through which a signal charge obtained by photoelectric conversion performed by the second pixel flows, and
a distance between the first voltage line and the first shield is smaller than a distance between the first voltage line and the first wiring line.

The twenty-second aspect is suitable for noise suppression. Specifically, the first shield of the twenty-second aspect is suitable for suppressing noise from entering the first wiring line due to the first voltage line.

Hereinafter, embodiments of the present disclosure are described in detail with reference to the drawings. Note that the embodiments, which will be described below, each illustrate a comprehensive or specific example. Numeric values, shapes, materials, constituting elements, arrangements and connection modes of the constituting elements, steps, the order of steps, and the like illustrated in the following embodiments are mere examples, and not intended to limit the present disclosure. Various aspects illustrated in this specification can be combined to each other as long as there is no inconsistency. Further, of constituting elements in the following embodiments, constituting elements that are not described in an independent claim representing the broadest concept will be described as optional constituting elements. In the following description, in some cases, constituting elements having substantially the same functions are denoted by common reference codes, and the descriptions thereof are omitted.

In this specification, the distance between two objects means the length of the shortest line segment connecting the two objects.

In this specification, terms such as a FD wiring line and a shield line are used in some cases. The FD wiring line means an element that may include a via. The shield line means an element that may include a via. Furthermore, in this specification, a via hole and a conductor inside the via hole may be collectively called as a “via”.

In this specification, ordinals such as first, second, third, . . . are used in some cases. In the case where an ordinal is used for a certain element, it does not necessarily mean that there is another element of same type having an earlier ordinal. The number of ordinal can be changed if need arises.

1-1. Structure of Imaging Device 100

Hereinafter, a first embodiment will be described. FIG. 1 is a diagram illustrating a structure of an imaging device 100 according to the present embodiment. Referring to FIG. 1, the structure of the imaging device 100 is described.

In an example described below, the imaging device 100 is a photoelectric conversion film multilayer type imaging device. The imaging device 100 has a configuration in which a photoelectric conversion film is stacked on one of surface sides of a semiconductor substrate.

The imaging device 100 includes a plurality of pixels 101 and peripheral circuits.

The plurality of pixels 101 form a pixel region. In the present embodiment, the plurality of pixels 101 are arranged two-dimensionally. Alternatively, the plurality of pixels 101 may be arranged one-dimensionally. In that case, the imaging device 100 is a line sensor.

In the example of FIG. 1, the plurality of pixels 101 are arranged in a row direction and a column direction. The row direction is the direction along which a row is extended. The column direction is the direction along which a column is extended. The vertical direction is the column direction. The horizontal direction is the row direction.

The imaging device 100 includes control signal lines CON1, control signal lines CON2, control signal lines CON3, output signal lines 111, power source lines CON4, and a power source line 112. The control signal line CON1, the control signal line CON2, and the control signal line CON3 are arranged in each row. The output signal line 111 and the power source line CON4 are arranged in each column. A reference voltage Vp is applied to the power source line 112, and the power source line 112 supplies the reference voltage Vp to all the pixels. Each of the pixels 101 is connected to corresponding one of the output signal lines 111 that are arranged in the corresponding columns. A detail description of the pixel 101 will be provided later.

The peripheral circuits include a vertical scanning circuit 102, column signal processing circuits 103, a horizontal signal readout circuit 104, constant current sources 105A, and constant current sources 105B. The vertical scanning circuit 102 is also referred to as a row scanning circuit. The column signal processing circuit 103 is also referred to as a row signal accumulation circuit. The horizontal signal readout circuit 104 is also referred to as a column scanning circuit.

The column signal processing circuit 103, the constant current source 105A, and the constant current source 105B are, for example, arranged in each of the columns of the pixels 101 that are arranged two-dimensionally. Next, an example of configuration of the peripheral circuits are described.

The vertical scanning circuit 102 is connected to the control signal line CON1, the control signal line CON2, and the control signal line CON3. By applying a predetermined voltage to the control signal line CON1, the vertical scanning circuit 102 selects, row by row, a plurality of pixels 101 arranged in each row. This enables readout of signal voltages of the selected pixels 101 and resetting of pixel electrodes, which will be described later.

The pixels 101 arranged in each column are electrically connected to the column signal processing circuit 103 via the output signal line 111 in each corresponding column. The column signal processing circuit 103 performs noise suppression signal processing typified by correlated double sampling, analog-digital conversion (AD conversion), and the like.

A plurality of column signal processing circuits 103, which are respectively provided in the corresponding columns, are electrically connected to the horizontal signal readout circuit 104. The horizontal signal readout circuit 104 sequentially reads out signals output from the plurality of column signal processing circuits 103 to a horizontal signal common line 113.

Voltages of a plurality of values are applied to the power source line CON4. For example, these voltages of a plurality of values are generated by a voltage source that is not illustrated. This voltage source may be provided inside the imaging device 100 or may be provided outside of the imaging device 100.

FIG. 2 is a circuit diagram illustrating an exemplary configuration of the pixel 101 in the imaging device 100 according to the present embodiment. The pixel 101 includes a photoelectric conversion unit 121 and a readout circuit 122.

The photoelectric conversion unit 121 is a photodetector. The photoelectric conversion unit 121 converts incident light, which is a light signal, to a signal charge, which is an electric signal.

The readout circuit 122 reads out the electric signal detected by the photoelectric conversion unit 121. The readout circuit 122 includes a band control unit 123, a charge accumulation region 124, a selection transistor 125, and an amplifier transistor 126.

The charge accumulation region 124 means part of a region where a signal charge detected by the photoelectric conversion unit 121 is accumulated. Specifically, the charge accumulation region 124 corresponds to a diffusion region provided in the semiconductor substrate. The charge accumulation region 124 can be called as a floating diffusion (FD).

In the following, the term “charge accumulation unit CSP” is used in some cases. The charge accumulation unit CSP means an overall configuration where the signal charge detected by the photoelectric conversion unit 121 is accumulated. The charge accumulation unit CSP includes the charge accumulation region 124.

For example, the photoelectric conversion unit 121 includes a first electrode, a second electrode, and a photoelectric conversion film. The photoelectric conversion film is located between the first electrode and the second electrode. The photoelectric conversion film is, for example, an organic photoelectric conversion film. The reference voltage Vp is applied to the first electrode. The charge accumulation region 124 is electrically connected to the second electrode. This allows the signal charge generated in the photoelectric conversion unit 121 to be accumulated in the charge accumulation region 124.

A method of accumulating signal charge in the charge accumulation region 124 is described specifically in the case where the photoelectric conversion unit 121 including the photoelectric conversion film is used.

When light falls on the photoelectric conversion film, electron-hole pairs are created by photoelectric conversion. In the case where there is a potential difference between the first electrode and the second electrode, created electrons or holes move toward the second electrode. For example, in the case where the reference voltage Vp applied to the first electrode is higher than the voltage of the second electrode, the holes move toward the second electrode. The voltage of the second electrode is, for example, a reset voltage. The holes move to the charge accumulation region 124 via a wiring line. This allows use of the holes as the signal charge.

The electrons may also be used as the signal charge.

In another example, like the pixel 101 illustrated in FIG. 3, a photodiode 127 is used as the photoelectric conversion unit. The photodiode 127 includes, for example, a n-type diffusion layer located on the surface of the substrate and a p-type diffusion layer located in the substrate. The p-type diffusion layer abuts onto the n-type diffusion layer. A ground potential or the reference voltage Vp is applied to the p-type layer of the photodiode 127. In one specific example, the photodiode 127 may be electrically connected to the charge accumulation region 124 via a transfer transistor, which is not illustrated. This specific example corresponds to an aspect of FIG. 26, which will be described later. In this specific example, the signal charge generated by the photodiode 127 is transferred to the charge accumulation region 124 via a transfer transistor and accumulated therein. However, as illustrated in FIG. 25, the transfer transistor is not essential. A case where the photodiode 127 is used as the photoelectric conversion unit will be described later with reference to FIG. 25 and FIG. 26.

Various elements having photoelectric conversion function can be used as the photoelectric conversion unit.

Referring back to FIG. 2, the charge accumulation region 124 is connected to the photoelectric conversion unit 121 with a wiring layer interposed therebetween. The charge accumulation region 124 is connected to a gate of the amplifier transistor 126. The amplifier transistor 126 outputs a signal that corresponds to the amount of the signal charge accumulated in the charge accumulation region 124 to the band control unit 123 and the selection transistor 125.

The band control unit 123 includes a reset transistor 131, a band control transistor 132, a capacitive element 133, and a capacitive element 134. The reset transistor 131 is used for resetting the charge accumulation region 124. The band control transistor 132 is used for limiting the band of a feedback signal fed back from the charge accumulation region 124 via the amplifier transistor 126.

During a “noise suppression period”, which will be described later, the signal charge read out from the charge accumulation region 124 is amplified by the amplifier transistor 126 and fed back to the charge accumulation region 124 after being band limited by the band control transistor 132. That is to say, the readout circuit 122 includes a feedback path that negatively feeds back the signal, which corresponds to the amount of the signal charge and is output from the amplifier transistor 126, to the charge accumulation region 124. This feedback path includes the charge accumulation region 124, the amplifier transistor 126, the band control transistor 132, and the capacitive element 134.

The selection transistor 125 is connected to the output signal line 111 shared by at least two pixels 101. The pixels 101 that share the output signal line 111 may belong to the same column. The output signal lines 111 may not be necessarily arranged in all the columns. For example, one output signal line 111 may be arranged for a plurality of columns, and the one output signal line 111 may be shared by the plurality of columns. Alternatively, a plurality of output signal lines 111 may be arranged for one column. For example, as illustrated in FIG. 4, a first output signal line 111A and a second output signal line 111B may be arranged in one column, a signal of the pixel 101 located in an odd-numbered row may be output to the first output signal line 111A, and a signal of the pixel 101 located in an even-numbered row may be output to the second output signal line 111B.

During a “readout period” and a “reset readout period”, which will be described later, a signal amplified by the amplifier transistor 126 is output to the output signal line 111 via the selection transistor 125. During these periods, no feedback path is formed. The “capacitive element” means a structure in which a dielectric material such as an insulation film is interposed between electrodes. Furthermore, the “electrode” is not limited to an electrode made of a metal and should be construed broadly in such a manner as to also include a polysilicon layer and the like. In this specification, the “electrode” may be a part of the semiconductor substrate.

1-2. Operation of Readout Circuit 122

The operation of the readout circuit 122 is now described. Note that strictly speaking, the drain and the source of a transistor are determined by voltages applied thereto, and in some cases, it is difficult to make a structural distinction. Accordingly, in the present embodiment, they are each referred to as one of drain and source or the other of drain and source. For the sake of expedience, in FIG. 2, a terminal on the lower side is referred to as one of drain and source, and a terminal on the upper side is referred to as the other of drain and source. Furthermore, the drain and the source are each made up of a diffusion region.

As illustrated in FIG. 2, the gate of the amplifier transistor 126 is electrically connected to the charge accumulation region 124. The other of drain and source of the amplifier transistor 126 is electrically connected to the other of drain and source of the band control transistor 132 and the one of drain and source of the selection transistor 125.

Furthermore, the one of drain and source of the band control transistor 132 is electrically connected to one end of the capacitive element 133. Furthermore, a reference voltage VR1 is applied to the other end of the capacitive element 133. This allows the band control transistor 132 and the capacitive element 133 to form a RC filter circuit.

The one of drain and source of the band control transistor 132 is also electrically connected to one end of the capacitive element 134. Furthermore, the other end of the capacitive element 134 is electrically connected to the charge accumulation region 124.

The gate of the band control transistor 132 is connected to the control signal line CON2. The voltage of the control signal line CON2 determines On and Off of the band control transistor 132.

For example, when the voltage of the control signal line CON2 is at a high level, the band control transistor 132 is turned on. As a result, the charge accumulation region 124, the amplifier transistor 126, the band control transistor 132, and the capacitive element 134 form the feedback path.

When the voltage of the control signal line CON2 decreases, the resistive component of the band control transistor 132 increases. This decreases a cutoff frequency, which is defined by this resistive component and the capacitive component in the feedback path, and the frequency range of a signal being fed back becomes narrower.

When the feedback path is formed, a signal output from the band control transistor 132 is attenuated by an attenuation circuit formed of the capacitive element 134 and a parasitic capacitance of the charge accumulation region 124, and the attenuated signal is fed back to the charge accumulation region 124. An attenuation ratio B is expressed by Cc/(Cc+Cfd), where Cc is the capacitance of the capacitive element 134 and Cfd is the parasitic capacitance of the charge accumulation region 124.

When the voltage of the control signal line CON2 decreases further and reaches a low level, the band control transistor 132 is turned off. In this case, no feedback path is formed.

The charge accumulation region 124 is also electrically connected to the one of drain and source of the reset transistor 131. The one of drain and source of the reset transistor 131 may function as the charge accumulation region 124. That is to say, the one of drain and source of the reset transistor 131 may be the charge accumulation region 124. The other of drain and source of the reset transistor 131 is connected to a node 129. Here, the node means a connection part that electrically connects a plurality of elements in an electric circuit and is a concept that includes a wiring line responsible for connecting such elements electrically and the like.

The gate of the reset transistor 131 is connected to the control signal line CON3. The voltage of the control signal line CON3 determines the state of the reset transistor 131. For example, when the voltage of the control signal line CON3 is at a high level, the reset transistor 131 is turned on. This resets the charge accumulation region 124 to the voltage of the node 129.

The other of drain and source of the selection transistor 125 is connected to the output signal line 111. The gate of the selection transistor 125 is connected to the control signal line CON1. The voltage of the control signal line CON1 determines On and Off of the selection transistor 125. For example, when the voltage of the control signal line CON1 is at a high level, the selection transistor 125 is turned on. This allows the amplifier transistor 126 and the output signal line 111 to be electrically connected to each other. When the voltage of the control signal line CON1 is at a low level, the selection transistor 125 is turned off. As a result, the selection transistor 125 and the output signal line 111 are electrically isolated from each other.

The one of drain and source of the amplifier transistor 126 is connected to the power source line CON4. During a reset period where the charge accumulation region 124 is reset, a voltage VA1 is applied from the power source line CON4 to the one of drain and source of the amplifier transistor 126. Furthermore, during the readout period where the charge is read out from the charge accumulation region 124, a voltage VA2 is applied from the power source line CON4 to the one of drain and source of the amplifier transistor 126. By controlling the voltage to be applied to the power source line CON4, the voltage applied to the one of drain and source of the amplifier transistor 126 is switched between the voltage VA1 and the voltage VA2.

For example, the voltage VA1 is GND. GND is a ground voltage. The voltage VA2 is VDD. VDD is a power supply voltage.

An amplifier circuit including the power source line CON4 and the amplifier transistor 126 may be provided for each of the pixels 101 or may be shared by a plurality of pixels 101. The number of elements per pixel can be reduced by sharing the amplifier circuit with a plurality of pixels 101.

The output signal line 111 may be connected to the constant current source 105A or 105B. When the selection transistor 125 is ON, the selection transistor 125, the amplifier transistor 126, and the constant current source 105A or 105B form a source follower circuit.

A signal corresponding to the signal charge accumulated in the charge accumulation region 124 is output to the output signal line 111 and is read out externally. Specifically, during the reset period and the noise suppression period, which will be described layer, the constant current source 105A is connected to the output signal line 111. During the readout period and the reset readout period, the constant current source 105B is connected to the output signal line 111.

Next, the operation of the readout circuit 122 is described using a timing chart. FIG. 5 is a timing chart illustrating an exemplary operation of the readout circuit 122. In each graph, the horizontal axis represents the time. The vertical axes respectively represent, from the top, the voltage level of the control signal line CON1, the voltage level of the control signal line CON2, the voltage level of the control signal line CON3, and the voltage level of the power source line CON4.

Exposure Period

A period from time t0 to time t1 corresponds to the exposure period.

During the period from time t0 to time t1, the voltage of the control signal line CON1 is at the low level, and thus the selection transistor 125 is being off. Furthermore, during this period, the signal charge generated in response to incident light is accumulated in the charge accumulation region 124.

Readout Period

A period from time t1 to time t2 corresponds to the readout period.

At time t1, the selection transistor 125 is turned on by changing the voltage of the control signal line CON1 to the high level. Furthermore, the voltage level of the power source line CON4 is the voltage VA2 (for example, VDD). In this state, the amplifier transistor 126 and the constant current source 105B form a source follower circuit. This allows the signal corresponding to the signal charge accumulated in the charge accumulation region 124 to be output to the output signal line 111. At this time, the amplification factor of the source follower circuit is, for example, about one.

Reset Period

A period from time t2 to time t3 corresponds to the reset period.

At time t2, the band control transistor 132 is turned on by changing the voltage of the control signal line CON2 to the high level. Furthermore, the voltage level of the power source line CON4 changes to the voltage VA1, and the voltage VA1 is applied to the one of drain and source of the amplifier transistor 126. The voltage VA1 is, for example, GND. Furthermore, the reset transistor 131 is turned on by changing the voltage of the control signal line CON3 to the high level. This resets the voltage of the charge accumulation region 124 to the voltage VA1.

Note that there is a resistive component in the power source line CON4. Because of this resistive component, there will be a voltage drop when a current flows through the power source line CON4. Therefore, strictly speaking, by turning on the reset transistor 131, the voltage of the charge accumulation region 124 is reset to a reference voltage, which deviates from the voltage VA1. In reality, there will be voltage drops caused by resistive components in other wiring lines, too. However, for the sake of expedience in description, the discussion regarding such voltage drops is omitted.

Noise Suppression Period

A period from time t3 to time t4 corresponds to the noise suppression period.

At time t3, the reset transistor 131 is turned off by changing the voltage of the control signal line CON3 to the low level. At this time, the readout circuit 122 forms the feedback path with an amplification factor of −A×B. Accordingly, kTC noise of the charge accumulation region 124 at the time of turning the reset transistor 131 off is suppressed by a factor of 1/(1+A×B). Here, A is the amplification factor of the amplifier transistor 126, and B is the attenuation rate. As described above, the attenuation rate is expressed by B=Cc/(Cc+Cfd), where Cc is the capacitance of the capacitive element 134, and Cfd is the parasitic capacitance of the charge accumulation region 124.

During the period from time t2 to time t3, the voltage of the control signal line CON2 is set to the voltage of the high level. On the other hand, during the period from time t3 to time t4, the voltage of the control signal line CON2 is set to the voltage of a middle level, which is between the high level and the low level. Therefore, compared with the period from time t2 to time t3, in the period from time t3 to time t4, the operating band of the band control transistor 132 is narrower.

By narrowing the operating band of the band control transistor 132, a noise suppression effect increases. On the other hand, by doing so, it takes a longer time to suppress noise, and therefore, it is necessary to make the period from time t3 to time t4 longer. Depending on an acceptable period for the period from time t3 to time t4, a designer can arbitrarily adjust the operating band of the band control transistor 132. Hereinafter, it is assumed that the operating band of the band control transistor 132 during the noise suppression period is sufficiently lower than the operating band of the amplifier transistor 126. Note that the noise suppression effect can be produced even in the case where the operating band of the band control transistor 132 during the noise suppression period is higher than the operating band of the amplifier transistor 126.

In the state where the operating band of the band control transistor 132 during the noise suppression period is lower than the operating band of the amplifier transistor 126, the kTC noise produced in the band control transistor 132 is suppressed by a factor of 1/(1+A×B)^{1/2}.

When the voltage of the control signal line CON2 is changed to the low level at time t4 in this state, the band control transistor 132 is turned off. The kTC noise remained in the charge accumulation region 124 at the time of turning the band control transistor 132 off is defined as the square-root of sum of squares of kTC noise caused by the reset transistor 131 and kTC noise caused by the band control transistor 132.

In this case, the kTC noise of the band control transistor 132 produced in the state where no suppression by feedback is present is (Cfd/Cs)^{1/2} times the kTC noise of the reset transistor 131 produced in the state where no suppression by feedback is present, where Cs is the capacitance of the capacitive element 133. With consideration of this point, the kTC noise in the case where the feedback is present is suppressed by a factor of [{1+(1+A×B)×Cfd/Cs}^{1/2}/(1+A×B)] compared with the case where no feedback is present.

Reset Readout Period

A period from time t4 to time t5 corresponds to the reset readout period.

At time t4, the voltage level of the power source line CON4 is set to the voltage VA2. The voltage VA2 is, for example, VDD. This allows the voltage VA2 to be applied to the one of drain and source of the amplifier transistor 126. In this state, the amplifier transistor 126 and the constant current source 105B form a source follower circuit. This allows a signal that corresponds to the reset voltage to be output to the output signal line 111.

For example, in a following circuit, correlated double sampling processing is performed, in which a difference between the signal read out during this reset readout period and the signal read out during the readout period is calculated. Subsequently, the calculated difference is output to outside of the imaging device 100 as a pixel signal.

The kTC noise is included in random noise. Here, the random noise means output fluctuation at the time when the electric signal converted by the photoelectric conversion unit 121 is zero. During the kTC noise is suppressed by a factor of [{1+(1+A×B)×Cfd/Cs}^{1/2}/(1+A×B)] during the noise suppression period. As a result, preferable image data in which random noise is suppressed can be obtained.

It is preferable that the capacitance Cs of the capacitive element 133 is greater than the capacitance Cc of the capacitive element 134.

Generally, when the capacitance of the charge accumulation region 124 is increased, the random noise is reduced. However, when converting a charge signal into a voltage signal in the charge accumulation region 124, the signal becomes smaller. Therefore, S/N does not improve in the end by simply increasing the capacitance of the charge accumulation region 124 itself.

In the present embodiment, the capacitive element 134 is interposed between the charge accumulation region 124 and the capacitive element 133. This interposition allows the charge accumulation region 124 and the capacitive element 133 to be electrically isolated from each other. Therefore, even in the case where the capacitance of the capacitive element 133 is increased, degradation of the signal in the charge accumulation region 124 is less likely to occur. Accordingly, the random noise can be effectively suppressed while suppressing degradation of the signal. Because of this, S/N can be improved effectively.

In the present embodiment, during the readout period, the signal of the charge accumulation region 124 is readout by the source follower circuit, and therefore, the amplification factor is about one. However, the amplification factor is not limited thereto, and the designer may change the amplification factor depending on S/N or the circuit range required for the system.

According to the present embodiment, the feedback for noise cancellation is performed within each pixel. Because of this, for example, compared with the case where the feedback is performed via the output signal line 111, the effect given by time constant of the output signal line 111 can be reduced. Accordingly, the noise cancellation can be performed at high speed. Furthermore, a greater noise suppression effect can be obtained by increasing the capacitance of the capacitive element arranged in the pixel 101.

1-3. Parasitic Capacitance Reduction (Shield Insertion)

As can be understood from the foregoing description regarding the operation of the readout circuit 122, the voltage of the power source line CON4 changes at the time of transition from the readout period to the reset period. That is to say, the voltage of the power source line CON4 changes at time t2 of FIG. 5. Furthermore, the voltage of the power source line CON4 also changes at the time of transition from the noise suppression period to the reset readout period. That is to say, the voltage of the power source line CON4 changes at time t4 of FIG. 5.

In some cases, a parasitic capacitance is generated between the power source line CON4 and the charge accumulation unit CSP. Because of the presence of this parasitic capacitance, voltage changes in the voltage of the power source line CON4 at time t2 and time t4 may cause the voltage of the charge accumulation unit CSP to change.

Based on this, in the present embodiment, a shield is provided for reducing the parasitic capacitance between the power source line CON4 and the charge accumulation unit CSP. Here, the shield means an electrostatic shield that cuts off effects of the electric field of a conductor. The shield may include a conductive material. The shield is held at a predetermined potential.

FIG. 6 is a plan view schematically illustrating an exemplary layout of a FD wiring line 141, the power source line CON4, and the first shield 171 of the pixel 101 in the configuration of FIG. 1. The FD wiring line 141 is connected to the charge accumulation region 124. The FD wiring line 141 is included in the charge accumulation unit CSP.

The material of the first shield 171 is, for example, a metal, a polysilicon, or a semiconductor.

In the example of FIG. 6, the first shield 171 includes a first shield line 171L. The first shield 171 may be made up of a shield line 171L. However, the first shield 171 may be made up of a non-line like body. The first shield 171 may include a shield line and a non-line like body.

In the example of FIG. 6, the first shield 171 is located, in plan view, between the FD wiring line 141 and the power source line CON4. The first shield 171 is placed closer to the power source line CON4 than to the FD wiring line 141. In plan view, no wiring line is present between the power source line CON4 and the first shield 171.

In this example, the plan view is an observation view from the direction vertical to the semiconductor substrate.

Specifically, in plan view, the first shield line 171L is located between the FD wiring line 141 and the power source line CON4. The first shield line 171L is placed closer to the power source line CON4 than to the FD wiring line 141. In plan view, no wiring line is present between the power source line CON4 and the first shield line 171L.

The power source line CON4 is extended in the column direction. However, the power source line CON4 may be extended in a different direction such as the row direction.

The first shield line 171L is extended in the column direction. However, the first shield line 171L may be extended in a different direction such as the row direction.

A non-continuous pattern may be provided in between two adjacent pixels 101 or within one pixel 101. The whole or part of such non-continuous pattern may function as a shield. The non-continuous pattern may be made up of a plurality of parts.

The plurality of parts may be electrically isolated from each other. In this case, voltages different from each other can be applied to the plurality of parts. In one specific example, each of the plurality of parts is connected to a voltage source of the corresponding fixed voltage within the pixel 101 in such a way that predetermined voltages are respectively supplied to the plurality of parts.

The plurality of parts may be electrically connected to each other. For example, a plurality of parts may be provided on a certain wiring layer, and a plurality of vias can be extended to the plurality of parts from corresponding wiring lines of a wiring layer adjacent to the certain wiring layer. In this way, the plurality of parts can be electrically connected.

The foregoing plurality of parts may include the first shield 171 and a second shield 172. In examples illustrated in FIG. 7A and FIG. 7B, the foregoing plurality of parts include the first shield line 171L and a second shield line 172L.

In the example illustrated in FIG. 7A, a gap G is formed between the first shield line 171L and the second shield line 172L. The first shield line 171L and the second shield line 172L are extended along a common axis CX. The common axis CX is extended in parallel to the power source line CON4.

In the example illustrated in FIG. 7B, the first shield line 171L and the second shield line 172L are not extended along a common axis. In this example, the first shield line 171L is extended in parallel to part of the power source line CON4. The second shield line 172L is extended in parallel to another part of the power source line CON4.

The power source line CON4 may be a power source line shared by all of the pixels as illustrated in FIG. 1. In this case, the power source line CON4 includes at least a wiring part extending in the column direction. For example, the power source line CON4 includes a plurality of wiring parts extending in the column direction within the pixel region. The wiring part is provided for each column. Furthermore, the plurality of wiring parts are electrically connected to each other outside of the pixel region.

As can be understood from the foregoing description, the voltage of the power source line CON4 changes at the time of transition from the readout period to the reset period. The voltage of the power source line CON4 also changes at the time of transition from the noise suppression period to the reset readout period. Because there is a parasitic capacitance between the power source line CON4 and the FD wiring line 141, these voltage changes reach the FD wiring line 141 in some cases. However, by adopting the configuration exemplified in FIG. 6, FIG. 7A, and FIG. 7B, the parasitic capacitance between the power source line CON4 and the FD wiring line 141 can be reduced, and the voltage changes in the FD wiring line 141 due to capacitive coupling can be suppressed.

The configuration exemplified in FIG. 8 may also be used. FIG. 8 is a plan view schematically illustrating an exemplary layout of the FD wiring line 141, power source lines CON4, and shields of the pixel 101 in the configuration of FIG. 4.

In the example of FIG. 8, the FD wiring line 141 is placed, in plan view, between a first shield 171A and a first shield 171B. Specifically, in plan view, the FD wiring line 141 is placed between a first shield line 171LA and a first shield line 171LB.

In the example of FIG. 8, in plan view, the first shield 171A is located between the FD wiring line 141 and a power source line CON4A. Specifically, in plan view, the first shield line 171LA is located between the FD wiring line 141 and the power source line CON4A.

In the example of FIG. 8, in plan view, the first shield 171B is located between the FD wiring line 141 and a power source line CON4B. Specifically, in plan view, the first shield line 171LB is located between the FD wiring line 141 and the power source line CON4B.

The first shield 171A and the first shield 171B may be electrically connected to each other or may be electrically isolated from each other.

In the examples of FIG. 4 and FIG. 8, the power source line CON4A and the power source line CON4B are placed in the same column. The power source line CON4A and the power source line CON4B are not electrically connected to each other in the pixel region. The power source line CON4A and the power source line CON4B are connected to the pixels 101 that are different from each other. Specifically, the power source line CON4A is electrically connected to the one of source and drain of the amplifier transistor 126 included in a certain pixel 101. The power source line CON4B is electrically connected to the one of source and drain of the amplifier transistor 126 included in a different pixel 101. For example, the power source line CON4A may be electrically connected to the one of source and drain of the amplifier transistor 126 included in pixels 101 located in odd rows, and the power source line CON4B may be electrically connected to the one of source and drain of the amplifier transistor 126 included in pixels 101 located in even rows.

In a different example, the power source line CON4A and the power source line CON4B are arranged in the same column. The power source line CON4A and the power source line CON4B are electrically connected to each other within the pixel region. The power source line CON4A and the power source line CON4B are connected to the same pixel 101. Specifically, the power source line CON4A and the power source line CON4B are electrically connected to the one of source and drain of the amplifier transistor 126 included in a certain pixel 101.

There may be a column A along which the power source line CON4A is provided while the power source line CON4B is not provided and a column B along which the power source line CON4B is provided while the power source line CON4A is not provided. The column A and the column B may be arranged in an alternating fashion. The number of the power source lines CON4 provided for one column may be one or two or more.

For example, in the case where a pixel 101A and a pixel 101B are adjacent to each other in the same column and the power source line CON4A and the power source line CON4B are provided for that column, it may be possible to connect the power source line CON4A to the pixel 101A and connect the power source line CON4B to the pixel 101B. In such a state, by providing the first shield 171A and the first shield 171B as in FIG. 8, capacitive coupling between an element within the pixel 101A and the power source line CON4B can be suppressed, and capacitive coupling between an element within the pixel 101B and the power source line CON4A can be suppressed. A technique relating to this will be described in detail in an example of the sixth embodiment by using FIG. 24B.

FIG. 9 illustrates a sectional view schematically representing a section at line IX-IX of FIG. 6. FIG. 10 illustrates a sectional view schematically representing a section at line X-X of FIG. 8. In the illustrated examples, a multilayer structure including the photoelectric conversion unit 121 and a semiconductor substrate 151 is formed. Here, there is described an example that uses a p-type silicon (Si) substrate as the semiconductor substrate 151.

In the illustrated examples, the semiconductor substrate 151, an interlayer insulating layer 152, the photoelectric conversion unit 121 are arranged in this order. The interlayer insulating layer 152 includes interlayer insulating layers 152A, 152B, 152C, and 152D. The interlayer insulating layers 152A, 152B, 152C, and 152D are stacked on top of each other in this order.

In the illustrated examples, the photoelectric conversion unit 121 includes a first electrode 153, a photoelectric conversion layer 154, and a second electrode 155. The first electrode 153, the photoelectric conversion layer 154, and the second electrode 155 are arranged in this order and stacked in this state. The first electrode 153 is provided on a surface of the photoelectric conversion layer 154 on the side which light from the subject is incident on. The photoelectric conversion layer 154 is placed between the first electrode 153 and the second electrode 155. Typically, the photoelectric conversion layer 154 is a film. The photoelectric conversion layer 154 is, for example, an organic photoelectric conversion film. The photoelectric conversion layer 154 may alternatively be an amorphous silicon film.

A shield electrode 156 is provided between the second electrode 155 of a certain pixel 101 and the second electrode 155 of a pixel 101 adjacent to this certain pixel 101. The shield electrode 156 improves color mixing characteristics by discharging charge obtained by photoelectric conversion at a boundary of the pixels 101 adjacent to each other. A fixed voltage may be supplied to the shield electrode 156.

In the example of FIG. 9, a voltage may be applied to the shield electrode 156 via a wiring line 159C and a via 159D. Specifically, a voltage may be applied to the shield electrode 156 from a power supply, which is not illustrated, via the wiring line 159C and the via 159D.

Although the illustration is omitted in FIG. 9, the amplifier transistor 126 is formed between the semiconductor substrate 151 and the photoelectric conversion unit 121. The FD wiring line 141 includes wiring lines 157A, 157B, and 157C and vias 158A, 1586, 158C, and 158D. The wiring lines 157A to 157C and the vias 158A to 158D are placed in the interlayer insulating layer 152.

In the example of FIG. 9, the wiring lines 157A to 157C are arranged in wiring layers different from each other. Specifically, the wiring line 157A is placed in a wiring layer 192A. The wiring line 157B is placed in a wiring layer 1926. The wiring line 157C is placed in a wiring layer 192C.

In the example of FIG. 9, the first shield 171, the power source line CON4, and the wiring line 157B are placed in the same wiring layer 192B. The first shield 171 is placed between the power source line CON4 and the wiring line 157B. This enables the suppression of capacitive coupling between the FD wiring line 141 and the power source line CON4 due to the parasitic capacitance.

In the example of FIG. 9, specifically, the first shield line 171L, the power source line CON4, and the wiring line 157B are placed in the same wiring layer 192B. The first shield line 171L is placed between the power source line CON4 and the wiring line 157B.

In the example of FIG. 10, the first shield 171A, the power source line CON4A, and the wiring line 157B are placed in the same wiring layer 192B. The first shield 171A is placed between the power source line CON4A and the wiring line 157B. This enables the suppression of the capacitive coupling between the FD wiring line 141 and the power source line CON4A due to the parasitic capacitance.

In the example of FIG. 10, specifically, the first shield line 171LA, the power source line CON4A, and the wiring line 157B are placed in the same wiring layer 192B. The first shield line 171LA is placed between the power source line CON4A and the wiring line 157B.

In the example of FIG. 10, the first shield 171B, the power source line CON4B, and the wiring line 157B are placed in the same wiring layer 192B. The first shield 171B is placed between the power source line CON4B and the wiring line 157B. This enables the suppression of the capacitive coupling between the FD wiring line 141 and the power source line CON4B due to the parasitic capacitance.

In the example of FIG. 10, specifically, the first shield line 171LB, the power source line CON4B, and the wiring line 157B are placed in the same wiring layer 192B. The first shield line 171LB is placed between the power source line CON4B and the wiring line 157B.

One power source line CON4 may be arranged in such a manner as to cross a plurality of wiring layers. Power source lines CON4 that are different from each other may be arranged in a plurality of wiring layers. In these cases, the parasitic capacitance can be suppressed by placing the first shield 171 (specifically, the first shield line 171L) in every wiring layer where the power source line CON4 is present. Specifically, in each of the foregoing wiring layers, the parasitic capacitance can be suppressed by arranging the first shield 171 as described in the present embodiment.

Typically, an unvarying voltage is supplied to the first shield 171 during a pixel readout period. Here, the pixel readout period includes the readout period, the reset period, and the reset readout period. As described in the above, the readout period corresponds to the period from time t1 to time t2 of FIG. 5. The reset period corresponds to the period from time t2 to time t3 of FIG. 5. The reset readout period corresponds to the period from time t4 to time t5 of FIG. 5.

A voltage source for supplying the voltage to the first shield 171 may be the same voltage source that supplies a voltage to another element. In this way, the number of power supplies in the imaging device 100 can be reduced. For example, one of GND, the power supply voltage VDD, and the voltage to be applied to the shield electrode 156 can be supplied to the first shield 171. However, a dedicated power supply for the first shield 171 may also be used.

FIG. 11 is a sectional view schematically illustrating a section of a modified example at line XI-XI illustrated in FIG. 6.

The example illustrated in FIG. 11 is different from the example illustrated in FIG. 9 in that the first shield 171 (specifically, the first shield line 171L) is placed in such a manner as to be placed across a plurality of wiring layers. Specifically, in FIG. 11, the first shield 171 is placed in three wiring layers 192A, 1926, and 192C. However, the first shield 171 may be placed in such a manner as to cross two wiring layers or may be placed in such a manner as to cross four or more wiring layers.

The FD wiring line 141 is also placed in the wiring layers 192A and 192C, which are different from the wiring layer 1926 in which the power source line CON4 is placed. In this case, it is conceivable to place, as illustrated in FIG. 11, the first shield 171 (specifically, the first shield line 171L) not only in the wiring layer 192B but also in the wiring layer 192A and the wiring layer 192C. This configuration has an advantage from the standpoint of the suppression of the capacitive coupling between the wiring line 157A of the FD wiring line 141 and the power source line CON4 and the capacitive coupling between the wiring line 157C of the FD wiring line 141 and the power source line CON4.

The imaging device 100 of the present embodiment may be described in the following manner.

The imaging device 100 includes a semiconductor substrate 151, a first pixel 101, and a first shield 171. The first pixel 101 includes a first diffusion region 124, a first wiring line 141, a first transistor 126, and a first voltage line CON4. The first diffusion region 124 is provided in the semiconductor substrate 151. The first wiring line 141 is connected to the first diffusion region 124. A first signal charge obtained by photoelectric conversion in the first pixel 101 flows through the first wiring line 141. The first transistor 126 includes a gate into which the first signal charge flows. The first voltage line CON4 makes up at least part of a voltage supply path to a drain or a source of the first transistor 126. Voltages VA1 and VA2, which are different from each other, are applied to the first voltage line CON4. A distance Da between the first voltage line CON4 and the first shield 171 is smaller than a distance Dd between the first voltage line CON4 and the first wiring line 141. The present embodiment is suitable for noise suppression. Specifically, the first shield 171 of the present embodiment is suitable for suppressing noise from entering the first wiring line 141 due to the first voltage line CON4.

The imaging device 100 may include a voltage supply circuit that applies voltages, which are different from each other, to the first voltage line CON4. In the present embodiment, the first diffusion region 124 corresponds to the charge accumulation region 124. The first wiring line 141 corresponds to the FD wiring line 141. The first transistor 126 corresponds to the amplifier transistor 126. The first voltage line CON4 corresponds to the power source line CON4. For example, the first signal charge obtained by photoelectric conversion of the photoelectric conversion unit 121 flows into the first diffusion region 124 and the gate of the first transistor 126 via the first wiring line 141 connected to the photoelectric conversion unit 121.

Specifically, the distance Da is the distance between the first voltage line CON4 present in the first pixel 101 and the first shield 171. The distance Dd is the distance between the first voltage line CON4 present in the first pixel 101 and the first wiring line 141 present in the first pixel 101. Furthermore, the distance Da is smaller than the distance Dd. The first shield 171 according to such configuration is suitable for suppressing noise from entering the first wiring line 141 laid in the first pixel 101 due to the first voltage line CON4 present in the first pixel 101.

Specifically, the first shield 171 can shield at least part of electric lines of force between the first wiring line 141 and the first voltage line CON4.

Typically, the voltages that are different from each other are DC voltages that are different from each other.

In the example of FIG. 2, the first voltage line CON4 is connected to the drain or the source of the first transistor 126.

The first shield 171 may be included in the first pixel 101 or may not be included in the first pixel 101.

The number of pixels corresponding the first pixels 101 may be one or two or more. All the pixels included in the imaging device 100 may correspond to the first pixel 101.

In the present embodiment, the voltage of the first voltage line CON4 is changed in the state where the voltage of the first shield 171 is fixed. For example, in the voltage supply circuit described above, the voltage of the first voltage line CON4 may be changed in the state where a fixed voltage is applied to the first shield 171. The first shield 171 according to such configuration is suitable for suppressing noise from entering the first wiring line 141 due to the first voltage line CON4. Note that the expression “the voltage of the first voltage line CON4 is changed in the state where the voltage of the first shield 171 is fixed” should not be construed as limited to indicate only an aspect in which the voltage of the first shield 171 is always constant. This expression should be construed as to include an aspect in which the voltage of the first shield 171 varies except for the time when the voltage of the first voltage line CON4 is changed.

In the example of FIG. 9, the imaging device 100 includes a first wiring layer 192B. The first wiring layer 192B is provided at a first position in the thickness direction of the semiconductor substrate 151. The first voltage line CON4 is placed in the first wiring layer 192B. The first shield 171 is placed in the first wiring layer 192B. The first wiring line 141 includes a first part located within the first wiring layer 192B. In plan view, the first shield 171 is located between the first part and the first voltage line CON4. As described above, in some cases, the first voltage line CON4 and the first shield 171 are placed in the same wiring layer. In such a case, the first shield of this example may produce the foregoing noise suppression effect. In this example, the first part corresponds to the wiring line 157B.

In the examples of FIG. 7A and FIG. 7B, the imaging device 100 includes a second shield 172. A distance Dx between the first voltage line CON4 and the second shield 172 is smaller than the distance Dd between the first voltage line CON4 and the first wiring line 141. The second shield according to such configuration is suitable for suppressing noise from entering the first wiring line 141 due to the first voltage line CON4.

Specifically, the distance Dx is the distance between the first voltage line CON4 present in the first pixel 101 and the second shield 172. The distance Dd is the distance between the first voltage line CON4 present in the first pixel 101 and the first wiring line 141 present in the first pixel 101. Furthermore, the distance Dx is smaller than the distance Dd. The second shield 172 according to such configuration is suitable for suppressing noise from entering the first wiring line 141 laid in the first pixel 101 due to the first voltage line CON4 present in the first pixel 101.

Specifically, the second shield 172 can shield at least part of electric lines of force between the first wiring line 141 and the first voltage line CON4.

The voltage of the first voltage line CON4 may be changed in the state where the voltage of the second shield 172 is fixed. The second shield 172 according to such configuration is suitable for suppressing noise from entering the first wiring line 141 due to the first voltage line CON4.

The first shield 171 and the second shield 172 may be electrically isolated from each other or may be electrically connected to each other.

The second shield 172 may be included in the first pixel 101 or may not be included in the first pixel 101.

The voltage to be applied to the first shield 171 and the voltage to be applied to the second shield 172 may be the same or may be different.

In the example of FIG. 6, the distance Da between the first shield 171 and the first voltage line CON4 is smaller than a distance Df between the first shield 171 and the first wiring line 141. The first shield 171 according to such configuration is suitable for suppressing noise from entering the first wiring line 141 due to the first voltage line CON4.

In the example of FIG. 6, in plan view, no wiring line is present between the first voltage line CON4 and the first shield 171. The first shield 171 according to such configuration is suitable for suppressing noise from entering the first wiring line 141 due to the first voltage line CON4.

In the example of FIG. 6, the imaging device 100 includes a first wiring layer 192B. The first wiring layer 192B is provided at the first position in the thickness direction of the semiconductor substrate 151. The first voltage line CON4 is placed in the first wiring layer 192B. The first shield 171 is placed in the first wiring layer 192B. The first wiring line 141 includes a first part located within the first wiring layer 192B. In plan view, the first shield 171 is located between the first part and the first voltage line CON4. In plan view, no wiring line is present between the first voltage line CON4 and the first shield 171.

In the example of FIG. 6, the first shield 171 includes a first shield line 171L. The distance Da between the first voltage line CON4 and the first shield line 171L is smaller than the distance Dd between the first voltage line CON4 and the first wiring line 141. The first shield line 171L according to such configuration is suitable for suppressing noise from entering the first wiring line 141 due to the first voltage line CON4.

Specifically, the distance Da is the distance between the first voltage line CON4 present in the first pixel 101 and the first shield line 171L. The distance Dd is the distance between the first voltage line CON4 present in the first pixel 101 and the first wiring line 141 present in the first pixel 101. Furthermore, the distance Da is smaller than the distance Dd. The first shield line 171L according to such configuration is suitable for suppressing noise from entering the first wiring line 141 laid in the first pixel 101 due to the first voltage line CON4 present in the first pixel 101.

Specifically, the first shield line 171L can shield at least part of electric lines of force between the first wiring line 141 and the first voltage line CON4.

In the examples of FIG. 7A and FIG. 7B, the second shield 172 includes the second shield line 172L. The distance Dx between the first voltage line CON4 and the second shield line 172L is smaller than the distance Dd between the first voltage line CON4 and the first wiring line 141. The second shield line 172L according to such configuration is suitable for suppressing noise from entering the first wiring line 141 due to the first voltage line CON4.

Specifically, the distance Dx is the distance between the first voltage line CON4 present in the first pixel 101 and the second shield line 172L. The distance Dd is the distance between the first voltage line CON4 present in the first pixel 101 and the first wiring line 141 present in the first pixel 101. Furthermore, the distance Dx is smaller than the distance Dd. The second shield line 172L according to such configuration is suitable for suppressing noise from entering the first wiring line 141 laid in the first pixel 101 due to the first voltage line CON4 present in the first pixel 101.

Specifically, the second shield line 172L can shield at least part of electric lines of force between the first wiring line 141 and the first voltage line CON4.

The first shield line 171L and the second shield line 172L may be electrically isolated from each other or may be electrically connected to each other.

In the examples of FIG. 7A and FIG. 7B, the first shield line 171L and the first voltage line CON4 are extended in parallel to each other in an area where the first shield line 171L and the first voltage line CON4 are closest to each other. The second shield line 172L and the first voltage line CON4 are extended in parallel to each other in an area where the second shield line 172L and the first voltage line CON4 are closest to each other.

In the example of FIG. 6, the distance Da between the first shield line 171L and the first voltage line CON4 is smaller than the distance Df between the first shield 171 and the first wiring line 141.

In the example of FIG. 6, in plan view, no wiring line is present between the first voltage line CON4 and the first shield line 171L.

In the example of FIG. 6, the imaging device 100 includes the first wiring layer 192B. The first wiring layer 192B is provided at the first position in the thickness direction of the semiconductor substrate 151. The first voltage line CON4 is placed in the first wiring layer 192B. The first shield line 171L is placed in the first wiring layer 192B. The first wiring line 141 includes a first part located within the first wiring layer 192B. In plan view, the first shield line 171L is located between the first part and the first voltage line CON4. In plan view, no wiring line is present between the first voltage line CON4 and the first shield line 171L.

In the example of FIG. 9, the imaging device 100 includes a first photoelectric conversion unit 121. The first photoelectric conversion unit 121 includes the first electrode 153, the second electrode 155, the photoelectric conversion layer 154 placed between the first electrode 153 and the second electrode 155. The photoelectric conversion layer 154 converts incident light into the first signal charge. The first wiring line 141 connects the second electrode 155 and the first diffusion region 124. The first wiring line 141 according to such configuration is suitable for allowing the first signal charge to flow from the first photoelectric conversion unit 121 to the first diffusion region 124. Furthermore, the first electrode 153 and the second electrode 155 are suitable for adjusting the amount of the first signal charge generated in the photoelectric conversion layer 154 by adjusting an electric field applied to the photoelectric conversion layer 154.

In the example of FIG. 9, in the thickness direction of the semiconductor substrate 151, the first voltage line CON4 and the first shield 171 are located between the first photoelectric conversion unit 121 and the semiconductor substrate 151.

In the example of FIG. 9, in the thickness direction of the semiconductor substrate 151, the first voltage line CON4 and the first shield line 171L are located between the first photoelectric conversion unit 121 and the semiconductor substrate 151.

In the example of FIG. 9, the imaging device 100 includes a third electrode 156. The third electrode 156 and the second electrode 155 are provided on one side of the photoelectric conversion layer 154. The third electrode 156 is electrically isolated from the second electrode 155. The third electrode 156 may be electrically connected to the first shield 171. This configuration is one example of the configuration in which the third electrode and the first shield can share a common voltage supply source. In the example of FIG. 9, the third electrode 156 corresponds to the shield electrode 156.

### Second Embodiment

Hereinafter, the second embodiment will be described. In the second embodiment, descriptions regarding contents similar to those of the first embodiment may be omitted in some cases.

As illustrated in FIG. 12, in the second embodiment, a power source line CON4 and a first shield 171 are arranged in wiring layers different from each other.

In the example of FIG. 12, the power source line CON4 is placed in a wiring layer 192B. The first shield 171 is placed in a wiring layer 192A.

Specifically, the first shield 171 includes a first shield line 171L. The power source line CON4 and the first shield line 171L are arranged in wiring layers different from each other. The first shield line 171L is placed in the wiring layer 192A.

There is a situation where a shield is not easy to provide on a wiring layer in which the power source line CON4 is placed. For example, such situation corresponds to a situation where a gap between the power source line CON4 and the FD wiring line 141 is narrow. Such situation also corresponds to a case where a via, which electrically connects a wiring layer in which the power source line CON4 is placed and another wiring layer, is placed between the power source line CON4 and the FD wiring line 141.

Under a situation such as described above, it is conceivable to place the shield on a wiring layer different from the wiring layer in which the power source line CON4 is placed. Even in the case where the shield is placed in the different wiring layer, the shield may suppress the capacitive coupling between the FD wiring line 141 and the power source line CON4 due to the parasitic capacitance. For example, in the case where the shield is arranged closer to the FD wiring line 141 than to the power source line CON4, the shield may shield part of electric lines of force between the power source line CON4 and the FD wiring line 141.

In the example of FIG. 12, the first shield 171 is placed in a wiring layer on the side of semiconductor substrate 151 of the wiring layer in which the power source line CON4 is placed. However, as described in a third embodiment which will be described below, the first shield 171 may be placed in a wiring layer on the side opposite to the side of the semiconductor substrate 151 of the wiring layer in which the power source line CON4 is placed. The first shield 171 may be placed both in the wiring layer on the side of the semiconductor substrate 151 and in the wiring layer on the side opposite to the side of the semiconductor substrate 151 of the wiring layer in which the power source line CON4 is placed.

Specifically, in the example of FIG. 12, the first shield line 171L is placed in the wiring layer on the side of the semiconductor substrate 151 of the wiring layer in which the power source line CON4 is placed. However, the first shield line 171L may be placed in the wiring layer on the side opposite to the side of the semiconductor substrate 151 of the wiring layer in which the power source line CON4 is placed. The first shield line 171L may be placed both in the wiring layer on the side of the semiconductor substrate 151 and in the wiring layer on the side opposite to the side of the semiconductor substrate 151 of the wiring layer in which the power source line CON4 is placed.

The imaging device 100 of the present embodiment may be described in the following manner.

The imaging device 100 includes a first wiring layer 192B and a second wiring layer 192C. The first wiring layer 1926 and the second wiring layer 192C are provided at positions different from each other in the thickness direction of the semiconductor substrate 151. A first voltage line CON4 is placed in the first wiring layer 1926. A first shield 171 is placed in the second wiring layer 192A. A first wiring line 141 includes a first part located within the second wiring layer 192A. In plan view, the first shield 171 is located between the first part and the first voltage line CON4. As described above, in some cases, the first voltage line and the first shield are arranged in wiring layers different from each other. In such a case, the first shield of the present embodiment may produce the foregoing noise suppression effect. In the example of FIG. 12, the first part corresponds to the wiring line 157A.

In the example of FIG. 12, the first wiring line 141 includes a second part located within the first wiring layer 1926. In plan view, the first shield 171 is located between the second part and the first voltage line CON4. In the example of FIG. 12, the second part corresponds to the wiring line 157A.

In the example of FIG. 12, the first shield line 171L is placed in the second wiring layer 192A. In plan view, the first shield line 171L is located between the first part and the first voltage line CON4. In plan view, the first shield line 171L is located between the second part and the first voltage line CON4.

In the example of FIG. 12, the first wiring layer 1926 in which the first voltage line CON4 is located and the second wiring layer 192A in which the first shield 171 is placed are adjacent to each other. However, the wiring layer in which the first voltage line CON4 is located and the wiring layer in which the first shield 171 is located may not be adjacent to each other.

### Third Embodiment

Hereinafter, the third embodiment will be described. In the third embodiment, descriptions regarding contents similar to those of the second embodiment may be omitted in some cases.

As illustrated in FIG. 13A, in the third embodiment, the first shield 171 is placed in a wiring layer 192C on the side opposite to the side of the semiconductor substrate 151 of the wiring layer 1926 in which the power source line CON4 is placed.

Specifically, the first shield 171 includes a first shield line 171L. The first shield line 171L is placed in the wiring layer 192C on the foregoing opposite side.

In the thickness direction of the semiconductor substrate 151, the second electrode 155, the first shield 171, the power source line CON4, and the semiconductor substrate 151 are arranged in this order. Specifically, in the thickness direction of the semiconductor substrate 151, the second electrode 155, the first shield line 171L, the power source line CON4, and the semiconductor substrate 151 are arranged in this order.

The second electrode 155 is included in the charge accumulation unit CSP. Accordingly, from the standpoint of noise reduction, it is advantageous to suppress not only the parasitic capacitance between the power source line CON4 and the FD wiring line 141 but also a parasitic capacitance between the power source line CON4 and the second electrode 155.

In view of the above, the imaging device 100 of the present embodiment includes characteristic features which may be described in the following manner.

The first shield 171 includes a first shield line 171L. In plan view, the first shield line 171L overlaps with at least part of a first voltage line CON4. Such configuration facilitates the shielding of electric lines of force between the first voltage line CON4 and a second electrode 155. The first shield line 171L according to such configuration is suitable for suppressing noise from entering the second electrode 155 due to the first voltage line CON4.

In the example of FIG. 13A, in plan view, the first shield line 171L overlaps with the whole of the first voltage line CON4. Such configuration particularly facilitates the shielding of electric lines of force between the first voltage line CON4 and the second electrode 155. Accordingly, this configuration is suitable for suppressing noise from entering the second electrode 155 due to the first voltage line CON4.

In the example of FIG. 13A, in plan view, the width of the first shield line 171L is wider than the width of the first voltage line CON4. Such configuration facilitates the shielding of electric lines of force between the first voltage line CON4 and the second electrode 155. Accordingly, this configuration is suitable for suppressing noise from entering the second electrode 155 due to the first voltage line CON4. Note that even in the case where the first shield line 171L and the first voltage line CON4 do not overlap in plan view, an effect of shielding electric lines of force between the first voltage line CON4 and the second electrode 155 can be obtained.

A configuration such as illustrated in FIG. 13B can also be adopted.

In the example of FIG. 13B, the imaging device 100 includes a plurality of wiring layers 192A to 192C that are provided at positions different from each other in the thickness direction of the semiconductor substrate 151. The plurality of wiring layers 192A to 192C includes a first wiring layer 192C. The first voltage line CON4 is placed in the first wiring layer 192C. In the case where, of the plurality of wiring layers 192A to 192C, the layer closest to the first photoelectric conversion unit 121 is defined as a proximal layer, the first wiring layer 192C is the proximal layer. This is suitable for avoiding the arrangement of the signal line and the power source line on the side of the photoelectric conversion layer 154 of the first voltage line CON4. This relaxes part of the design that has been made in consideration of the voltage changes in the first voltage line CON4 and thus facilitates wiring.

In some cases, the size of the interlayer insulating layer 152D in the thickness direction of the semiconductor substrate 151 is large, and the gap between the second electrode 155 and the proximal layer 192C is large. Although it is not particularly limited, in such cases, it is advantageous to adopt the configuration of FIG. 13B. This is because, in such cases, it is less likely to have a large parasitic capacitance between the second electrode 155 and the first voltage line CON4.

A configuration such as illustrated in FIG. 13C can also be adopted.

In the example of FIG. 13C, a distance Dc between the first shield 171 and the first voltage line CON4 is smaller than a distance Db between the second electrode 155 and the first voltage line CON4 in the thickness direction of the semiconductor substrate 151. The distance Dc is smaller than the distance Dd between the first voltage line CON4 and the first wiring line 141 in plan view.

In the example of FIG. 13C, specifically, the distance Dc between the first shield line 171L and the first voltage line CON4 is smaller than the distance Db between the second electrode 155 and the first voltage line CON4 in the thickness direction of the semiconductor substrate 151. The distance Dc is smaller than the distance Dd between the first voltage line CON4 and the first wiring line 141 in plan view.

### Fourth Embodiment

Hereinafter, the fourth embodiment will be described. In the fourth embodiment, descriptions regarding contents similar to those of the third embodiment may be omitted in some cases.

As illustrated in FIG. 14, in the fourth embodiment, the imaging device 100 includes a capacitive element 185. The capacitive element 185 includes an electrode 181, an electrode 183, and a dielectric layer 182. The electrode 181 and the electrode 183 are arranged on the opposite sides to each other with the dielectric layer 182 interposed therebetween.

In the example of FIG. 14, the capacitive element 185 is a metal insulator metal (MIM) capacitor. The electrode 181 can be referred to as a first MIM electrode 181. The electrode 183 can be referred to as a second MIM electrode 183.

As the capacitive element 185, the capacitive element 133 or the capacitive element 134 can be adopted.

The first MIM electrode 181 is electrically connected to a power source, which is not illustrated. In one example, this power source supplies a fixed voltage to the first MIM electrode 181. The second MIM electrode 183 is electrically connected to a second diffusion region 184. The second diffusion region 184 is provided in the semiconductor substrate 151. The second diffusion region 184 is a diffusion region different from the first diffusion region 124. The second diffusion region 184 may be the other of drain and source of the reset transistor 131.

As described above, there is a situation where a shield is not easy to provide on the same wiring layer as that of the power source line CON4. For example, such situation corresponds to a situation where a gap between the power source line CON4 and the FD wiring line 141 is narrow. Such situation also corresponds to a case where a via, which electrically connects a wiring layer in which the power source line CON4 is placed and another wiring layer, is placed between the power source line CON4 and the FD wiring line 141. In such a situation, the electrode of the capacitive element 185 of the present embodiment may shield part of electric lines of force between the power source line CON4 and the FD wiring line 141. This may enable the suppression of the capacitive coupling between the FD wiring line 141 and the power source line CON4 due to the parasitic capacitance.

In the example of FIG. 14, the first MIM electrode 181 is responsible for shielding part of electric lines of force between the power source line CON4 and the FD wiring line 141. It can be considered that the first MIM electrode 181 is included in the first shield 171.

The imaging device 100 of the present embodiment may be described in the following manner.

The imaging device 100 includes a capacitive element 185. The capacitive element 185 includes a pair of electrodes 181 and 183 and a dielectric layer 182. The dielectric layer 182 is interposed between the pair of electrodes 181 and 183. A first shield 171 includes one of the pair of electrodes 181 and 183. The electrode of the capacitive element 185 according to such configuration may function as a shield for the foregoing noise suppression.

In the example of FIG. 14, the foregoing one of the pair of the electrodes 181 and 183 is closer to the first voltage line CON4 than the other of the pair of the electrodes 181 and 183 is. A distance De between the first voltage line CON4 and the foregoing one of the pair of the electrodes 181 and 183 is smaller than a distance Dd between the first wiring line 141 and the first voltage line CON4. A proximal electrode according to such configuration is suitable for suppressing noise from entering the first wiring line 141 due to the first voltage line. In the example of FIG. 14, the foregoing one of the pair of the electrodes 181 and 183 corresponds to the first MIM electrode 181.

### Fifth Embodiment

Hereinafter, the fifth embodiment will be described. In the fifth embodiment, descriptions regarding contents similar to those of the first embodiment may be omitted in some cases.

As illustrated in FIG. 15, in an imaging device 200 of the fifth embodiment, a plurality of pixels 201 are arranged in the row direction and the column direction as is the case with the imaging device 100 of the first embodiment illustrated in FIG. 1.

In the example of FIG. 1, for each column, one output signal line 111 is provided. The output signal line 111 of each column is connected to the pixels 101 in that column. The constant current source 105A or the constant current source 105B may be connected to the output signal line 111 of each column.

In the example of FIG. 15, for each column, one signal line 211 is provided. The signal line 211 of each column is connected to the pixels 201 in that column. The constant current source 1056 or the power source line CON4 may be connected to the signal line 211 of each column.

Furthermore, in the example of FIG. 15, a signal line 212 is connected to each pixel 201. The constant current source 105A or the power source VDD may be connected to the signal line 212.

FIG. 16 illustrates an exemplary circuit diagram of the pixel 201 in the imaging device 200 according to the present embodiment. In the example of FIG. 16, a circuit configuration different from the circuit configuration of the first embodiment illustrated in FIG. 2 is adopted.

In the following, the circuit configuration of FIG. 2 is described while comparing with the circuit configuration of FIG. 16. Hereinafter, following the description regarding FIG. 2, a terminal on the lower side of FIG. 16 is referred to as one of drain and source, and a terminal on the upper side is referred to as the other of drain and source.

Specifically, in the example of FIG. 2, the power source line CON4 is connected to the one of drain and source of the amplifier transistor 126. The constant current source 105A or the constant current source 1056 may be electrically connected to the other of drain and source of the amplifier transistor 126 via the selection transistor 125.

In the example of FIG. 16, the constant current source 1056 or the power source line CON4 may be electrically connected to the one of drain and source of the amplifier transistor 126 via the selection transistor 125. The constant current source 105A or the power source VDD may be electrically connected to the other of drain and source of the amplifier transistor 126.

In the example of FIG. 2, the one of drain and source of the selection transistor 125 is electrically connected to the other of drain and source of the amplifier transistor 126. The one of drain and source of the selection transistor 125 is electrically connected to the band control transistor 132.

In the example of FIG. 16, the other of drain and source of the selection transistor 125 is electrically connected to the one of drain and source of the amplifier transistor 126. The constant current source 1056 or the power source line CON4 may be electrically connected to the one of drain and source of the selection transistor 125.

Next, the operation of a readout circuit 222 is described using a timing chart. FIG. 17 is a timing chart for illustrating an exemplary operation of the readout circuit 222. The horizontal axis of each graph represents the time. The vertical axes respectively represent, from the top, the voltage level of the control signal line CON1, the voltage level of the control signal line CON2, the voltage level of the control signal line CON3, and the voltage level of the power source line CON4.

Note that in the example to be described below, the power source line CON4 has one voltage value. However, the power source line CON4 may have a plurality of voltage values.

Exposure Period

A period from time t0 to time t1 corresponds to the exposure period.

During the period from time t0 to time t1, the voltage of the control signal line CON1 is at a low level, and thus the selection transistor 125 is being off. Furthermore, during this period, the signal charge generated in response to incident light is accumulated in the charge accumulation region 124.

Readout Period

A period from time t1 to time t2 corresponds to the readout period.

At time t1, the selection transistor 125 is turned on by changing the voltage of the control signal line CON1 to the high level. Furthermore, during the readout period, the power source VDD is electrically connected to the amplifier transistor 126, and the constant current source 105B is electrically connected to the selection transistor 125. In this state, the amplifier transistor 126 and the constant current source 1056 form a source follower circuit. According to this, a signal corresponding to the signal charge accumulated in the charge accumulation region 124 is output to the signal line 211.

Reset Period

A period from time t2 to time t3 corresponds to the reset period.

At time t2, the band control transistor 132 is turned on by changing the voltage of the control signal line CON2 to the high level. During the reset period, the constant current source 105A is electrically connected to the amplifier transistor 126, the power source line CON4 is electrically connected to the selection transistor 125, and the voltage VA1 is applied to the one of drain and source of the amplifier transistor 126. Furthermore, at time t2, the reset transistor 131 is turned on by changing the voltage of the control signal line CON3 to the high level. This resets the voltage of the charge accumulation region 124 to the voltage VA1.

At time t3, the reset transistor 131 is turned off by changing the voltage of the control signal line CON3 to the low level. At this time, the readout circuit 122 forms the feedback path with an amplification factor of −A×B. Accordingly, kTC noise of the charge accumulation region 124 at the time of turning the reset transistor 131 off is suppressed by a factor of 1/(1+A×B).

Noise Suppression Period

A period from time t3 to time t4 corresponds to the noise suppression period.

During the period from time t2 to time t3, the voltage of the control signal line CON2 is set to the voltage of the high level. Whereas, during the period from time t3 to time t4, the voltage of the control signal line CON2 is set to the voltage of the middle level, which is between the high level and the low level.

When the voltage of the control signal line CON2 is set to the low level at time t4 in this state, the band control transistor 132 is turned off.

As a result, as is the case with the first embodiment, the noise is suppressed by a factor of [{1+(1+A×B)×Cfd/Cs}^{1/2}/(1+A×B)] compared with the case where no feedback is present.

Reset Readout Period

A period from time t4 to time t5 corresponds to the reset readout period.

At time t4, again, the power source VDD is electrically connected to the amplifier transistor 126, and the constant current source 105B is electrically connected to the selection transistor 125. In this state, the amplifier transistor 126 and the constant current source 105B form a source follower circuit. This allows a signal that corresponds to the reset voltage to be output to the signal line 211.

As can be understood from the foregoing description regarding the operation of the readout circuit 222, a connection destination to which the signal line 211 is electrically connected is switched between the constant current source 105B and the power source line CON4. This switching causes a change in the voltage of the signal line 211.

Specifically, the voltage of the signal line 211 changes at the time of transition from the readout period to the reset period. That is to say, the voltage of the signal line 211 changes at time t2 of FIG. 17. Furthermore, the voltage of the signal line 211 also changes at the time of transition from the noise suppression period to the reset readout period. That is to say, the voltage of the signal line 211 changes at time t4 of FIG. 17.

In some cases, there is a parasitic capacitance between the signal line 211 and the charge accumulation unit CSP. In the case where this parasitic capacitance is present, the voltage changes in the voltage of the signal line 211 at time t2 and time t4 may cause the voltage of the charge accumulation unit CSP to change.

Based on this, in the present embodiment, a shield is provided for reducing the parasitic capacitance between the signal line 211 and the charge accumulation unit CSP.

FIG. 18 is a plan view schematically illustrating an exemplary layout of the charge accumulation region 124, the signal line 211, and the first shield 171 of the pixel 201 in the configuration of FIG. 15. As is the case with the first embodiment, the FD wiring line 141 is connected to the charge accumulation region 124.

In the example of FIG. 18, the first shield 171 is located, in plan view, between the FD wiring line 141 and the signal line 211. In this example, as is the case with the first embodiment, the plan view is an observation view from the direction vertical to the semiconductor substrate 151.

In the example of FIG. 18, the first shield line 171L is placed closer to the signal line 211 than to the FD wiring line 141. In plan view, no wiring line is present between the signal line 211 and the shield line.

The signal line 211 is extended in the column direction. However, the signal line 211 may be extended in a different direction such as the row direction.

The first shield line 171L is extended in the column direction. However, the first shield line 171L may be extended in a different direction such as the row direction.

As can be understood from the foregoing description, the voltage of the signal line 211 changes at the time of transition from the readout period to the reset period. The voltage of the signal line 211 also changes at the time of transition from the noise suppression period to the reset readout period. In the case where there is a parasitic capacitance between the signal line 211 and the FD wiring line 141, these voltage changes sometimes reach the FD wiring line 141. However, by adopting the configuration exemplified in FIG. 18, the parasitic capacitance between the signal line 211 and the FD wiring line 141 can be reduced, and the voltage changes in the FD wiring line 141 due to capacitive coupling can be suppressed.

The imaging device 200 of the present embodiment may be described in the following manner.

The imaging device 200 includes a semiconductor substrate 151, a first pixel 201, and a first shield 171. The first pixel 201 includes a first diffusion region 124, a first wiring line 141, a first transistor 126, and a first voltage line 211. The first diffusion region 124 is provided in the semiconductor substrate 151. The first wiring line 141 is connected to the first diffusion region 124. A first signal charge obtained by photoelectric conversion in the first pixel 201 flows through the first wiring line 141. The first voltage line 211 forms at least part of a voltage supply path to the drain or the source of the first transistor 126. Voltages that are different from each other are applied to the first voltage line 211. A distance Da between the first voltage line 211 and the first shield 171 is smaller than a distance Dd between the first voltage line 211 and the first wiring line 141. The present embodiment is suitable for noise suppression. Specifically, the first shield 171 of the present embodiment is suitable for suppressing noise from entering the first wiring line 141 due to the first voltage line 211.

in the present embodiment, the first voltage line 211 corresponds to the signal line 211. The voltage applied to the signal line 211 may change at the time when the signal line 211 is connected to the constant current source 1056 and when the signal line 211 is connected to the power source line CON4.

Specifically, the distance Da is the distance between the first voltage line 211 present in the first pixel 201 and the first shield 171. The distance Dd is the distance between the first voltage line 211 present in the first pixel 201 and the first wiring line 141 present in the first pixel 201. Furthermore, the distance Da is smaller than the distance Dd. The first shield 171 according to such configuration is suitable for suppressing noise from entering the first wiring line 141 laid in the first pixel 201 due to the first voltage line 211 present in the first pixel 201.

Specifically, the first shield 171 can shield at least part of electric lines of force between the first wiring line 141 and the first voltage line 211.

Typically, the voltages that are different from each other are DC voltages that are different from each other.

The techniques described in the first to fourth embodiments can be used in the fifth embodiment.

### Sixth Embodiment

Hereinafter, the sixth embodiment will be described. In the sixth embodiment, descriptions regarding contents similar to those of the first embodiment may be omitted in some cases.

In the first embodiment, the suppression of the parasitic capacitance between the FD wiring line 141 and the power source line CON4 is described. However, as illustrated in the timing chart of FIG. 5, the voltage also changes in the control signal line CON1, the control signal line CON2, the control signal line CON3 during the pixel readout period. In the case where there is a parasitic capacitance between each signal line and the FD wiring line 141, the voltage of the FD wiring line 141 varies due to the voltage change in each signal line via the corresponding parasitic capacitance. Accordingly, from the standpoint of noise reduction, it is advantageous to suppress a parasitic capacitance between the FD wiring line 141 and the control signal line CON1, a parasitic capacitance between the FD wiring line 141 and the control signal line CON2, and a parasitic capacitance between the FD wiring line 141 and the control signal line CON3. The same applies to the fifth embodiment.

Taking this into account, it is conceivable to lay out the charge accumulation region 124, the control signal line CON1, the control signal line CON2, the control signal line CON3, and the first shield 171 of the pixel 101 of FIG. 1 as exemplified in FIG. 19.

In the example of FIG. 19, the first shield 171 is located, in plan view, between the FD wiring line 141 and the control signal line CON1. The first shield 171 is located, in plan view, between the FD wiring line 141 and the control signal line CON2. The first shield 171 is located, in plan view, between the FD wiring line 141 and the control signal line CON3.

In the example of FIG. 19, the first shield 171 includes the first shield line 171L. The first shield 171 may be made up of a shield line 171L. However, the first shield 171 may be made up of a non-line like body. The first shield 171 may include a shield line and a non-line like body.

In the example of FIG. 19, the first shield line 171L is located, in plan view, between the FD wiring line 141 and the control signal line CON1. The first shield line 171L is located, in plan view, between the FD wiring line 141 and the control signal line CON2. The first shield line 171L is located, in plan view, between the FD wiring line 141 and the control signal line CON3.

In the example of FIG. 19, the first shield 171 is placed closer to the control signal line CON1 than to the FD wiring line 141. In plan view, no wiring line is present between the control signal line CON1 and the first shield 171.

Specifically, the first shield line 171L is placed closer to the control signal line CON1 than to the FD wiring line 141. In plan view, no wiring line is present between the control signal line CON1 and the first shield line 171L.

In the example of FIG. 19, the control signal line CON 1, the control signal line CON 2, and the control signal line CON 3 are extended in the row direction. However, the control signal line CON 1, the control signal line CON 2, and the control signal line CON 3 may be extended in the column direction.

In the example of FIG. 19, the first shield line 171L is extended in the row direction. However, the first shield line 171L may be extended in the column direction.

As described above, a non-continuous pattern may be provided in between two adjacent pixels 101 or within one pixel 101. The whole or part of such non-continuous pattern may function as a shield. The non-continuous pattern may be made up of a plurality of parts that are electrically isolated from each other. As described with reference to FIG. 7A and FIG. 7B, the foregoing plurality of parts may include the first shield 171 and the second shield 172. The foregoing plurality of parts may include the first shield line 171L and the second shield line 172L.

The arrangement of the control signal line CON1, the control signal line CON2, and the control signal line CON3 is not limited to the arrangement of FIG. 19. For example, from the side closer to the first shield 171, the control signal line CON3, the control signal line CON2, and the control signal line CON1 may be arranged in this order. From the side closer to the first shield line 171L, the control signal line CON3, the control signal line CON2, and the control signal line CON1 may be arranged in this order.

FIG. 20 illustrates a sectional view schematically representing a section at line XX-XX of FIG. 19.

In the example of FIG. 19 and FIG. 20, the first shield 171, the control signal line CON1, the control signal line CON2, and the control signal line CON3 are placed in the same wiring layer 1926. Specifically, the first shield line 171L, the control signal line CON1, the control signal line CON2, and the control signal line CON3 are placed in the same wiring layer 192B.

The control signal line CON1, the control signal line CON2, and the control signal line CON3 may be arranged in wiring layers different from each other. In that case, as illustrated in FIG. 21, the first shield 171 can be placed between each control signal line and the FD wiring line 141 in plan view. Specifically, in plan view, the first shield line 171L can be placed between each control signal line and the FD wiring line 141.

In the example of FIG. 21, the control signal line CON1 is placed in the wiring layer 192C. The control signal line CON2 is placed in the wiring layer 1926. The control signal line CON3 is placed in the wiring layer 192A. Furthermore, in the example of FIG. 21, the first shield 171 is placed across a plurality of wiring layers. Specifically, in FIG. 21, the first shield 171 is placed in three wiring layers, which are the wiring layer 192C, the wiring layer 1926, and the wiring layer 192A. The first shield 171 includes, specifically, the first shield line 171L. In the wiring layer 192C, the first shield line 171L is placed between the control signal line CON1 and the FD wiring line 141.

In the wiring layer 1926, the first shield line 171L is placed between the control signal line CON2 and the FD wiring line 141.

In the wiring layer 192A, the first shield line 171L is placed between the control signal line CON3 and the FD wiring line 141.

Such configuration can suppress capacitive coupling between the FD wiring line 141 and the control signal line CON1, capacitive coupling between the FD wiring line 141 and the control signal line CON2, and capacitive coupling between the FD wiring line 141 and the control signal line CON3.

A layout different from the layout of FIG. 19 can also be adopted. FIG. 22 is a plan view schematically illustrating a different exemplary layout of the charge accumulation region 124, the control signal line CON1, the control signal line CON2, the control signal line CON3, and the shield of the pixel 101 in the configuration of FIG. 1.

In the example of FIG. 22, in plan view, the FD wiring line 141 is located between a first shield 171A and a first shield 171B. The first shield 171A is located, in plan view, between the FD wiring line 141 and the control signal line CON1. The first shield 171B is located, in plan view, between the FD wiring line 141 and the control signal line CON3.

Specifically, the FD wiring line 141 is located, in plan view, between a first shield line 171LA and a first shield line 171LB. The first shield line 171LA is located, in plan view, between the FD wiring line 141 and the control signal line CON1. The first shield line 171LB is located, in plan view, between the FD wiring line 141 and the control signal line CON3.

FIG. 23 illustrates a sectional view schematically representing a section at line XXIII-XXIII of FIG. 22.

In the example of FIG. 23, the control signal line CON1, the control signal line CON2, and the control signal line CON3 are placed in the same wiring layer 192B. The first shield 171A and the first shield 171B are also placed in that wiring layer 192B. Specifically, the first shield line 171LA and the first shield line 171LB are placed in the wiring layer 192B.

Even in the case where the control signal lines are arranged on both sides of the FD wiring line 141, the capacitive coupling can be suppressed by providing the first shields 171A and 171B as illustrated in FIG. 22 and FIG. 23.

A layout that can suppress capacitive coupling between pixels adjacent to each other may also be adopted. FIG. 24A illustrates an example of such layout. FIG. 24A is a plan view schematically illustrating an exemplary layout for a pixel 101A and a pixel 101B that are adjacent to each other in the same column.

In the example of FIG. 24A, each of the pixel 101A and the pixel 101B includes the charge accumulation region 124, the control signal line CON1, the control signal line CON2, the control signal line CON3, the first shield 171A, and the first shield 171B.

Specifically, each of the pixel 101A and the pixel 101B includes the charge accumulation region 124, the control signal line CON1, the control signal line CON2, the control signal line CON3, the first shield line 171LA, and the first shield line 171LB.

In the pixel 101A, in plan view, the FD wiring line 141 is located between the first shield 171A and the first shield 171B. In the pixel 101A, in plan view, the first shield 171A is located between the FD wiring line 141 and the control signal line CON1. The same applies to the pixel 101B.

Specifically, in the pixel 101A, in plan view, the FD wiring line 141 is located between the first shield line 171LA and the first shield line 171LB. In the pixel 101A, in plan view, the first shield line 171LA is located between the FD wiring line 141 and the control signal line CON1. The same applies to the pixel 101B.

Furthermore, in plan view, the first shield 171B of the pixel 101B is located between the FD wiring line 141 of the pixel 101B and the control signal line CON3 of the pixel 101A.

Specifically, in plan view, the first shield line 171LB of the pixel 101B is located between the FD wiring line 141 of the pixel 101B and the control signal line CON3 of the pixel 101A.

According to the configuration of FIG. 24A, the first shield 171A of the pixel 101A can suppress capacitive coupling between the FD wiring line 141 of the pixel 101A and the control signal line CON1 of the pixel 101A. The first shield 171A of the pixel 101B can suppress capacitive coupling between the FD wiring line 141 of the pixel 101B and the control signal line CON1 of the pixel 101B. Furthermore, the first shield 171B of the pixel 101B can suppress capacitive coupling between the FD wiring line 141 of the pixel 101B and the control signal line CON3 of the pixel 101A.

The pixel 101A may include a first shield 171C, and the first shield 171C may be located between the FD wiring line 141 of the pixel 101B and one of the control signal lines of the pixel 101A, which is the closest to the FD wiring line 141 of the pixel 101B. Because of the first shield 171C of the pixel 101A, this aspect can also suppress capacitive coupling between the FD wiring line 141 of the pixel 101B and the control signal lines CON1 to CON3 of the pixel 101A.

The layout of FIG. 24B can also be adopted. In the example of FIG. 24B, a distance Da between the power source line CON4 of a second pixel 101B and the first shield 171 is smaller than a distance Dd between the power source line CON4 of the second pixel 101B and the first wiring line 141 of the first pixel 101A. This can suppress capacitive coupling between the power source line CON4 of the second pixel 101B and the first wiring line 141 of the first pixel 101A.

The imaging device 100 according to FIG. 24B may be described in the following manner.

The imaging device 100 includes a semiconductor substrate 151, a first pixel 101A, a second pixel 101B, and a first shield. The first pixel 101A and the second pixel 101B are adjacent to each other. The first pixel 101A includes a first diffusion region 124 and a first wiring line 141. The first diffusion region 124 is provided in the semiconductor substrate 151. The first wiring line 141 is connected to the first diffusion region 124. A first signal charge obtained by photoelectric conversion in the first pixel 101A flows through the first wiring line 141. The second pixel 101B includes a first transistor 126 and a first voltage line CON4. The first transistor 126 includes a gate into which a second signal charge obtained by photoelectric conversion in the second pixel 101B flows. The first voltage line CON4 forms at least part of a voltage supply path to the drain or the source of the first transistor 126. The voltages VA1 and VA2 that are different from each other are applied to the first voltage line CON4. A distance Da between the first voltage line CON4 and the first shield 171 is smaller than a distance Dd between the first voltage line CON4 and the first wiring line 141. This configuration is suitable for noise suppression. Specifically, the first shield 171 according to such configuration is suitable for suppressing noise from entering the first wiring line 141 due to the first voltage line CON4.

As is the case with the first embodiment, in the example of FIG. 24B, the first diffusion region 124 corresponds to the charge accumulation region 124. The first wiring line 141 corresponds to the FD wiring line 141. The first transistor 126 corresponds to the amplifier transistor 126. The first voltage line CON4 corresponds to the power source line CON4.

Specifically, the distance Da is the distance between the first voltage line CON4 present in the second pixel 101B and the first shield 171. The distance Dd is the distance between the first voltage line CON4 present in the second pixel 101B and the first wiring line 141 present in the first pixel 101A. Furthermore, the distance Da is smaller than the distance Dd. The first shield 171 according to such configuration is suitable for suppressing noise from entering the first wiring line 141 laid in the first pixel 101A due to the first voltage line CON4 present in the second pixel 101B.

Specifically, the first shield 171 can shield at least part of electric lines of force between the first wiring line 141 and the first voltage line CON4.

Typically, the voltages that are different from each other are DC voltages that are different from each other.

In this example, the first voltage line CON4 is connected to the drain or the source of the first transistor 126.

Specifically, in the example of FIG. 24B, a second diffusion layer of the second pixel 101B is provided in the semiconductor substrate 151. A second wiring line of the second pixel 101B is connected to the second diffusion layer. A second signal charge obtained by photoelectric conversion in the second pixel 101B flows through the second wiring line. The second diffusion layer is electrically connected to the gate of the first transistor 126 of the second pixel 101B. The second diffusion layer corresponds to the charge accumulation region 124 of the second pixel 101B. The second wiring line corresponds to the FD wiring line 141 of the second pixel 101B.

The first shield 171 may be a constituting element of the first pixel 101A or a constituting element of the second pixel 101B or may not be any of constituting elements of these pixels 101A and 101B.

Specifically, the pixels of the imaging device form an array. The first pixel 101A and the second pixel 101B are adjacent to each other in the row direction or the column direction of the array.

The amplifier transistor 126 and the first voltage line CON4 of the second pixel 101B may have characteristic features similar to those of the amplifier transistor 126 and the first voltage line CON4 of the second pixel 101B described above in the first embodiment and the like. In addition, characteristic features of the embodiments described above can be combined with the example of FIG. 24B.

### Seventh Embodiment

Hereinafter, the seventh embodiment will be described. In the seventh embodiment, descriptions regarding contents similar to those of the first embodiment may be omitted in some cases.

The photoelectric conversion unit is not limited to the one described in the first embodiment. In the seventh embodiment, a photodiode 127 is used as the photoelectric conversion unit.

Even in the case where the photodiode 127 is used as the photoelectric conversion unit, the layout illustrated in FIG. 6 can be adopted. FIG. 25 illustrates one example of such a case and is a sectional view at line XXV-XXV illustrated in FIG. 6.

In the example of FIG. 25, the charge accumulation region 124 and the semiconductor substrate 151 make up the photodiode 127. As is the case with the first embodiment, it can be said that the charge accumulation region 124 is provided in the semiconductor substrate 151.

The charge accumulation region 124 is connected to the FD wiring line 141. In the example of FIG. 25, the FD wiring line 141 electrically connects the charge accumulation region 124 and the gate of the amplifier transistor 126, which is not illustrated.

In the example of FIG. 25, part of the FD wiring line 141, the first shield 171, and the power source line CON4 are placed in the same wiring layer 192A. Specifically, the part of the FD wiring line 141, the first shield line 171L, and the power source line CON4 are placed in the same wiring layer 192A.

Specifically, the FD wiring line 141 includes a via 158A and a wiring line 157A. The foregoing part of the FD wiring line 141 is the wiring line 157A. For example, a signal charge generated in the photodiode 127 flows into the gate of the amplifier transistor 126 illustrated in FIG. 3 from the charge accumulation region 124 via the FD wiring line 141.

Characteristic features of the embodiments described above can be combined with the example of FIG. 25.

For example, in the example of FIG. 25, a distance Da between the first voltage line CON4 and the first shield 171 is smaller than a distance Dd between the first voltage line CON4 and the first wiring line 141.

In the example of FIG. 25, in the wiring layer 192A, the first shield 171 is placed between part of the first wiring line 141 and the first voltage line CON4. This enables the suppression of the capacitive coupling between the first wiring line 141 and the first voltage line CON4 due to the parasitic capacitance.

In the imaging device, the layout illustrated in FIG. 6 can be adopted even in the case where a transfer transistor is used together with the photodiode. FIG. 26 is an exemplary sectional view at line XXVI-XXVI illustrated in FIG. 6 in such case. In the following, the description that overlaps with the example of FIG. 25 is omitted in some cases.

As is the case with the example of FIG. 25, in the example of FIG. 26, the charge accumulation region and the semiconductor substrate 151 make up the photodiode 127.

In the example of FIG. 26, a charge accumulation region 124 that is different from the charge accumulation region of the photodiode 127 is provided in the semiconductor substrate 151. The photodiode 127 and the charge accumulation region 124 may be electrically connected to each other via transfer transistors 161 and 162.

In the example of FIG. 26, two transfer transistors 161 and 162 are used. However, the number of the transfer transistors to be used may be one or may be greater than or equal to three. For example, a signal charge generated in the photodiode 127 flows into the charge accumulation region 124 via the transistors 161 and 162 and then flows into the gate of the amplifier transistor 126 illustrated in FIG. 3 from the charge accumulation region 124 via the first wiring line 141.

As described above, in the imaging device according to the present embodiment, a first photodiode 127 is made up of the semiconductor substrate 151 and the first diffusion region 124 or the semiconductor substrate 151 and a diffusion region. That is to say, the first photodiode 127 is present in the semiconductor substrate 151 and includes the first diffusion region 124 or the diffusion region. The first photodiode 127 converts incident light into a first signal charge. The first wiring line 141 electrically connects the first transistor 126 and the first diffusion region 124.

Imaging Devices According to FIG. 19 and FIG. 24A

The imaging device 100 according to FIG. 24A described above may be described in the following manner.

The imaging device 100 includes a semiconductor substrate 151, a first pixel 101A, and a first shield. The first pixel 101A includes a first diffusion region 124, a first wiring line 141, a first transistor, and a first voltage line. The first diffusion region 124 is provided in the semiconductor substrate 151. The first wiring line 141 is connected to the first diffusion region 124. A signal charge obtained by photoelectric conversion in the first pixel 101A flows through the first wiring line 141. The first voltage line is connected to the gate of the first transistor. Voltages that are different from each other are applied to the first voltage line. The distance between the first voltage line and the first shield is smaller than the distance between the first voltage line and the first wiring line 141. Such configuration is suitable for noise suppression. Specifically, the first shield according to such configuration is suitable for suppressing noise from entering the first wiring line due to the first voltage line.

A combination of the first transistor and the first voltage line may correspond to the combination of the selection transistor 125 of the first pixel 101A and the control signal line CON1 of the first pixel 101A. The combination of the first transistor and the first voltage line may correspond to the combination of the band control transistor 132 of the first pixel 101A and the control signal line CON2 of the first pixel 101A. The combination of the first transistor and the first voltage line may correspond to the combination of the reset transistor 131 of the first pixel 101A and the control signal line CON3 of the first pixel 101A. The first shield may correspond to the first shield 171A extending in the area surrounded by dashed two-dotted line, which represents the first pixel 101A, in FIG. 24A. Specifically, the first shield may correspond to the first shield line 171LA extending in the area surrounded by the dashed two-dotted line.

Specifically, the distance between the first voltage line present in the first pixel 101A and the first shield is smaller than the distance between the first voltage line present in the first pixel 101A and the first wiring line 141 present in the first pixel 101A. The first shield according to such configuration is suitable for suppressing noise from entering the first wiring line 141 laid in the first pixel 101A due to the first voltage line present in the first pixel 101A.

Specifically, the first shield can shield at least part of electric lines of force between the first wiring line 141 and the first voltage line.

Typically, the voltages that are different from each other are DC voltages that are different from each other.

The first shield may be a constituting element of the first pixel 101A or may not be any of constituting elements of the first pixel 101A.

The foregoing description regarding FIG. 24A are also true in the example of FIG. 19.

The imaging device 100 according to FIG. 24A described above may be described in the following manner.

The imaging device 100 includes a semiconductor substrate 151, a first pixel 101A, a second pixel 101B, and a first shield. The first pixel 101A and the second pixel 101B are adjacent to each other. The first pixel 101A includes a first transistor and a first voltage line. The first voltage line is connected to the gate of the first transistor. Voltages that are different from each other are applied to the first voltage line. The second pixel 101B includes a first diffusion region 124 and a first wiring line 141. The first diffusion region 124 is provided in the semiconductor substrate 151. The first wiring line 141 is connected to the first diffusion region 124. A signal charge obtained by photoelectric conversion in the second pixel 101B flows through the first wiring line 141. The distance between the first voltage line and the first shield is smaller than the distance between the first voltage line and the first wiring line 141. Such configuration is suitable for noise suppression. Specifically, the first shield according to such configuration is suitable for suppressing noise from entering the first wiring line due to the first voltage line.

A combination of the first transistor and the first voltage line may correspond to the combination of the selection transistor 125 of the first pixel 101A and the control signal line CON1 of the first pixel 101A. The combination of the first transistor and the first voltage line may correspond to the combination of the band control transistor 132 of the first pixel 101A and the control signal line CON2 of the first pixel 101A. The combination of the first transistor and the first voltage line may correspond to the combination of the reset transistor 131 of the first pixel 101A and the control signal line CON3 of the first pixel 101A. The first shield may correspond to the first shield 171B extending in the area surrounded by dashed two-dotted line, which represents the second pixel 101B, in FIG. 24A. Specifically, the first shield may correspond to the first shield line 171LB extending in the area surrounded by the dashed two-dotted line.

Specifically, the distance between the first voltage line present in the first pixel 101A and the first shield is smaller than the distance between the first voltage line present in the first pixel 101A and the first wiring line 141 present in the second pixel 101B. The first shield according to such configuration is suitable for suppressing noise from entering the first wiring line 141 laid in the second pixel 101B due to the first voltage line present in the first pixel 101A.

Specifically, the first shield can shield at least part of electric lines of force between the first wiring line 141 and the first voltage line.

Typically, the voltages that are different from each other are DC voltages that are different from each other.

The first shield may be a constituting element of the first pixel 101A or a constituting element of the second pixel 101B or may not be any of constituting elements of these pixels 101A and 101B.

Specifically, the pixels of the imaging device form an array. The first pixel 101A and the second pixel 101B are adjacent to each other in the row direction or the column direction of the array.

Camera System

A camera system can be formed by using the imaging device according to one of the embodiments described above. In the following, one example of the camera system is described with reference to FIG. 27.

A camera system 300 illustrated in FIG. 27 includes an optical system 310, an imaging device 100, a signal processing circuit 360, a system controller 370, and a display device 380. The camera system 300 is, for example, a smartphone, a digital camera, a video camera, and the like. Instead of the imaging device 100, it is also possible to use the imaging device 200.

The signal processing circuit 360 is, for example, a digital signal processor (DSP). The signal processing circuit 360 receives output data from the imaging device 100 and performs processing such as gamma correction, color interpolation processing, spatial interpolation processing, automatic white balance, and the like.

The display device 380 is, for example, a liquid crystal display or an organic electro-luminescence (EL) display. The display device 380 may include an input interface such as a touch panel. This allows a user to select and control a processing content of the signal processing circuit 360 and to set image capturing conditions using a touch pen and the input interface.

The system controller 370 controls the whole of the camera system 300. The system controller 370 is typically a semiconductor integrated circuit and is, for example, a CPU.

The camera system 300 of FIG. 27 can display a captured image on the display device 380. Therefore, the captured image can be checked promptly. Furthermore, it becomes possible to perform graphic user interface (GUI) control using the display device 380.

The imaging devices according to the present disclosure are useful as various imaging devices. Furthermore, the imaging devices according to the present disclosure are applicable to digital cameras, digital video cameras, cellular phones with cameras, medical cameras such as electronic endoscopes, vehicle-mounted cameras, cameras for robots.

What is claimed is:

1. An imaging device comprising:
a semiconductor substrate; a first pixel that performs photoelectric conversion; and a first shield, wherein
the first pixel includes
a first diffusion region in the semiconductor substrate,
a first wiring line connected to the first diffusion region, wherein a first signal charge obtained by photoelectric conversion performed by the first pixel flows through the first wiring line,
a first transistor including a gate into which the first signal charge flows via the first wiring line, and
a first voltage line that is at least part of a voltage supply path to a drain or a source of the first transistor, wherein voltages that are different from each other are to be applied to the first voltage line, and
a distance between the first voltage line and the first shield is less than a distance between the first voltage line and the first wiring line.

2. An imaging device comprising:
a semiconductor substrate; a first pixel that performs photoelectric conversion; a second pixel that performs photoelectric conversion; and a first shield, wherein
the first pixel and the second pixel are adjacent to each other,
the first pixel includes
a first diffusion region in the semiconductor substrate, and
a first wiring line connected to the first diffusion region, wherein a first signal charge obtained by photoelectric conversion performed by the first pixel flows through the first wiring line,
the second pixel includes
a first transistor including a gate into which a second signal charge obtained by photoelectric conversion performed by the second pixel flows, and
a first voltage line that is at least part of a voltage supply path to a drain or a source of the first transistor, wherein voltages that are different from each other are to be applied to the first voltage line, and
a distance between the first voltage line and the first shield is less than a distance between the first voltage line and the first wiring line.

3. The imaging device according to claim 1, wherein
a voltage of the first voltage line is changed in a state where a voltage of the first shield is fixed.

4. The imaging device according to claim 1, further comprising:
a first wiring layer located at a first position in a thickness direction of the semiconductor substrate, wherein
the first wiring layer includes the first voltage line, the first shield, and a first part of the first wiring line, and
in plan view, the first shield is located between the first part and the first voltage line.

5. The imaging device according to claim 1, further comprising:
a first wiring layer and a second wiring layer that are located at positions different from each other in a thickness direction of the semiconductor substrate, wherein
the first wiring layer includes the first voltage line,
the second wiring layer includes the first shield and a first part of the first wiring line, and
in plan view, the first shield is located between the first part and the first voltage line.

6. The imaging device according to claim 1, further comprising:
a second shield, wherein
a distance between the first voltage line and the second shield is less than the distance between the first voltage line and the first wiring line.

7. The imaging device according to claim 1, wherein
the distance between the first shield and the first voltage line is less than a distance between the first shield and the first wiring line.

8. The imaging device according to claim 1, wherein
in plan view, no wiring line is present between the first voltage line and the first shield.

9. The imaging device according to claim 1, wherein
the first shield includes a first shield line, and
a distance between the first voltage line and the first shield line is less than the distance between the first voltage line and the first wiring line.

10. The imaging device according to claim 1, further comprising:
a capacitive element, wherein
the capacitive element includes
a pair of electrodes including a first electrode, and
a dielectric layer between the pair of electrodes, and
the first shield includes the first electrode of the pair of electrodes.

11. The imaging device according to claim 10, wherein
the pair of electrodes further includes a second electrode,
the first electrode of the pair of electrodes is closer to the first voltage line than the second electrode of the pair of electrodes is, and
a distance between the first electrode of the pair of electrodes and the first voltage line is less than the distance between the first wiring line and the first voltage line.

12. The imaging device according to claim 1, wherein
the first pixel further includes a first photoelectric converter,
the first photoelectric converter includes a first electrode, a second electrode, and a photoelectric conversion layer located between the first electrode and the second electrode,
the photoelectric conversion layer converts incident light into the first signal charge, and
the first wiring line connects the second electrode and the first diffusion region.

13. The imaging device according to claim 12, wherein
in the thickness direction of the semiconductor substrate, the first voltage line and the first shield are located between the first photoelectric converter and the semiconductor substrate.

14. The imaging device according to claim 12, further comprising:
wiring layers located at positions different from each other in the thickness direction of the semiconductor substrate, wherein
the wiring layers include a first wiring layer that includes the first voltage line, and
the first wiring layer is closest to the first photoelectric converter among the wiring layers.

15. The imaging device according to claim 12, wherein
in the thickness direction of the semiconductor substrate, the second electrode, the first shield, the first voltage line, and the semiconductor substrate are arranged in this order.

16. The imaging device according to claim 15, wherein
the first shield includes a first shield line, and
in plan view, the first shield line overlaps with at least part of the first voltage line.

17. The imaging device according to claim 16, wherein
in the plan view, the first shield line entirely covers the first voltage line.

18. The imaging device according to claim 12, further comprising:
a third electrode, wherein
the third electrode and the second electrode are located on the same side of the photoelectric conversion layer,
the third electrode is electrically isolated from the second electrode, and
the third electrode is electrically connected to the first shield.

19. The imaging device according to claim 12, wherein
the distance between the first shield and the first voltage line is
less than a distance between the second electrode and the first voltage line in the thickness direction of the semiconductor substrate, and
less than the distance between the first voltage line and the first wiring line in plan view.

20. The imaging device according to claim 1, wherein
the first pixel further includes a first photodiode in the semiconductor substrate,
the first diffusion region is included in the first photodiode,
the first photodiode converts incident light into the first signal charge, and
the first wiring line electrically connects the first transistor and the first diffusion region.

21. The imaging device according to claim 1, wherein
the first pixel further includes a first photodiode in the semiconductor substrate,
the first diffusion region is connected to the first photodiode via one or more transistors,
the first photodiode converts incident light into the first signal charge, and
the first wiring line electrically connects the first transistor and the first diffusion region.

22. An imaging device comprising:
a semiconductor substrate; a first pixel that performs photoelectric conversion; and a first shield, wherein
the first pixel includes
a first diffusion region in the semiconductor substrate,
a first wiring line connected to the first diffusion region, wherein a signal charge obtained by photoelectric conversion performed by the first pixel flows through the first wiring line,
a first transistor, and
a first voltage line that is at least part of a voltage supply path to a gate of the first transistor, wherein voltages that are different from each other are to be applied to the first voltage line, and
a distance between the first voltage line and the first shield is less than a distance between the first voltage line and the first wiring line.

23. An imaging device comprising:
a semiconductor substrate; a first pixel that performs photoelectric conversion; a second pixel that performs photoelectric conversion; and a first shield, wherein
the first pixel and the second pixel are adjacent to each other,
the first pixel includes
a first transistor, and
a first voltage line that is at least part of a voltage supply path to a gate of the first transistor, wherein voltages that are different from each other are to be applied to the first voltage line,
the second pixel includes
a first diffusion region in the semiconductor substrate, and
a first wiring line connected to the first diffusion region, wherein a signal charge obtained by photoelectric conversion performed by the second pixel flows through the first wiring line, and
a distance between the first voltage line and the first shield is less than a distance between the first voltage line and the first wiring line.

24. The imaging device according to claim 1, further comprising:
a voltage supply circuit that applies the voltages.

25. The imaging device according to claim 24, wherein
the voltage supply circuit changes a voltage of the first voltage line in a state where a fixed voltage is applied to the first shield.

26. The imaging device according to claim 1, wherein
the first shield reduces a parasitic capacitance between the first voltage line and the first wiring line.

27. The imaging device according to claim 2, wherein
a voltage of the first voltage line is changed in a state where a voltage of the first shield is fixed.

28. The imaging device according to claim 2, further comprising:
a first wiring layer located at a first position in a thickness direction of the semiconductor substrate, wherein
the first wiring layer includes the first voltage line, the first shield, and a first part of the first wiring line, and
in plan view, the first shield is located between the first part and the first voltage line.

29. The imaging device according to claim 2, further comprising:
a first wiring layer and a second wiring layer that are located at positions different from each other in a thickness direction of the semiconductor substrate, wherein
the first wiring layer includes the first voltage line,
the second wiring layer includes the first shield and a first part of the first wiring line, and
in plan view, the first shield is located between the first part and the first voltage line.
